(19) United States
(12) Patent Application Publication
(10) Pub. No.: US 2025/0022874 A1
(43) Pub. Date: Jan. 16, 2025

(54) SEMICONDUCTOR DEVICE

(71) Applicant: ROHM CO., LTD., Kyoto-shi (JP)

(72) Inventor: Atsushi NOCHIDA, Kyoto-shi (JP)

(73) Assignee: ROHM CO., LTD., Kyoto-shi (JP)

(21) Appl. No.: 18/901,507

(22) Filed: Sep. 30, 2024

Related U.S. Application Data
(63) Continuation of application No. PCT/JP2023/006638, filed on Feb. 24, 2023.

(30) Foreign Application Priority Data
Mar. 31, 2022 (JP) 2022-061086
Mar. 31, 2022 (JP) 2022-061087

(51) Int. Cl. H01L 27/06; H01L 29/06; H01L 29/417; H01L 29/739

(52) U.S. Cl. CPC H01L 27/0664; H01L 29/0623; H01L 29/41708; H01L 29/7397

(57) ABSTRACT

A semiconductor device includes a chip that has a first main surface on one side and a second main surface on the other side, an IGBT region provided in an inner portion of the first main surface, an outer peripheral region provided in a peripheral edge portion of the first main surface, a first conductivity type well region formed in a surface layer portion of the first main surface in the outer peripheral region so as to define the IGBT region, an insulating film that covers the well region, a well connection electrode embedded in the insulating film so as to be connected to the well region, and a second conductivity type cathode region formed in a surface layer portion of the second main surface in the outer peripheral region so as to oppose the well connection electrode, and that forms a diode with the well region.

### CROSS-REFERENCE TO RELATED APPLICATIONS

The present application is a bypass continuation of International Patent Application No. PCT/JP2023/006638 filed on Feb. 24, 2023, that claims priority to Japanese Patent Application No. 2022-061086 filed on Mar. 31, 2022 and Japanese Patent Application No. 2022-061087 filed on Mar. 31, 2022, the entire disclosures of those applications are incorporated herein by reference in their entireties.

### BACKGROUND

### 1. Field of the Disclosure

The present disclosure relates to a semiconductor device.

### 2. Description of the Related Art

US2010/0090248A1 discloses a semiconductor device that includes an RC-IGBT (Reverse Conducting-Insulating Gate Bipolar Transistor).

### BRIEF DESCRIPTION OF DRAWINGS

FIG. 1 is a plan view showing a semiconductor device according to an embodiment.

FIG. 2 is a plan view showing a layout example within a first main surface.

FIG. 3 is a plan view showing a layout example of a well region, a gate wiring, and a cathode region.

FIG. 4 is a plan view showing an essential portion of a chip.

FIG. 5 is a cross-sectional view showing a cross-sectional structure taken along line V-V in FIG. 4 with the cathode region according to the first layout example.

FIG. 6 is a cross-sectional view showing a cross-sectional structure taken along line VI-VI in FIG. 4 with the cathode region according to the first layout example.

FIG. 7 is a cross-sectional view showing a cross-sectional structure taken along line VII-VII in FIG. 4 with the cathode region according to the first layout example.

FIG. 8 is a cross-sectional view showing a cross-sectional structure of a peripheral edge portion of the chip with the cathode region according to the first layout example.

FIG. 9 is a cross-sectional view for illustrating an arrangement location of the cathode region.

FIG. 10 is a cross-sectional view showing the current density of a forward current in a case in which the cathode region is arranged at a gate reference position.

FIG. 11 is a cross-sectional view showing the current density of a forward current in a case in which the cathode region is arranged at a first well reference position.

FIG. 12 is a cross-sectional view showing the current density of a forward current in a case in which the cathode region is arranged at a second well reference position.

FIG. 13 is a graph showing the relationship between the forward current and the forward voltage for FIGS. 10 to 12.

FIG. 14A is a graph showing the relationship between the arrangement location of the cathode region and the forward current IF.

FIG. 14B is a graph for illustrating a first setting example of a prohibited range, a first permitted range, and a second permitted range based on the result in FIG. 14A.

FIG. 14C is a graph for illustrating a second setting example of a prohibited range, a first permitted range, and a second permitted range based on the result in FIG. 14A.

FIG. 15 is a graph showing the relationship between the peak surge current and the forward voltage when the arrangement location of the cathode region is adjusted.

FIG. 16 is a cross-sectional view showing a cross-sectional structure of a peripheral edge portion of the chip with a cathode region according to a second layout example.

FIG. 17 is a cross-sectional view showing a cross-sectional structure of a peripheral edge portion of the chip with a cathode region according to a third layout example.

FIG. 18 is a cross-sectional view showing a cross-sectional structure of a peripheral edge portion of the chip with a cathode region according to a fourth layout example.

FIG. 19 is a cross-sectional view showing a cross-sectional structure of a peripheral edge portion of the chip with a cathode region according to a fifth layout example.

FIG. 20 is a cross-sectional view showing a cross-sectional structure of a peripheral edge portion of the chip with a cathode region according to a sixth layout example.

### DETAILED DESCRIPTION OF THE PREFERRED EMBODIMENTS

Embodiments will hereinafter be described in detail with reference to the accompanying drawings. The accompanying drawings are schematic, not strictly illustrated, and not necessarily to scale. Also, structures that t correspond to each other between some of the accompanying drawings are designated by the same reference sign and will not be described or only described shortly to avoid duplication. Structures not described or only described shortly should be applied with descriptions that have been made for the corresponding structures.

A phrase “substantially equal,” when used in a description in which there is a comparison target, includes a numerical value (form) that is equal to the numerical value (form) of the comparison target, as well as a numerical error (form error) within a range of ±10% relative to the numerical value (form) of the comparison target. In the embodiments, terms “first,” “second,” “third,” and so on may be used, which are symbols not intended to limit the name of each structure but assigned to the name of each structure in order to clarify the order of description thereof.

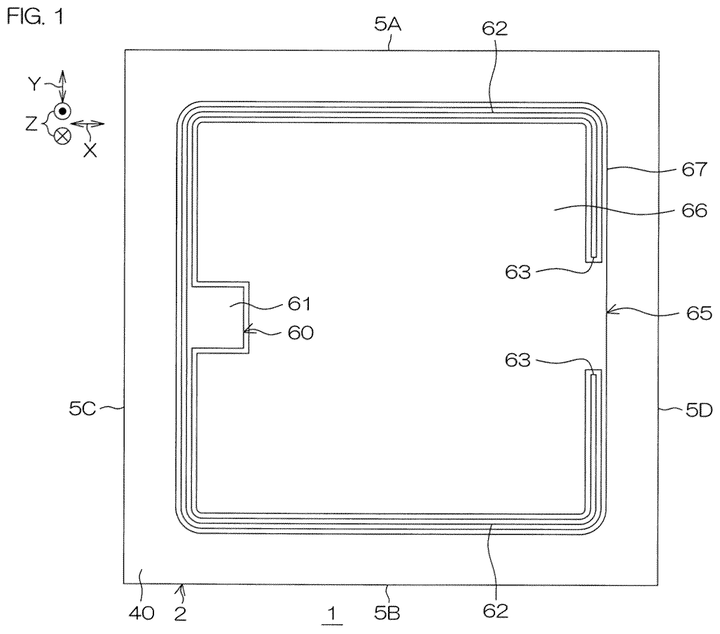

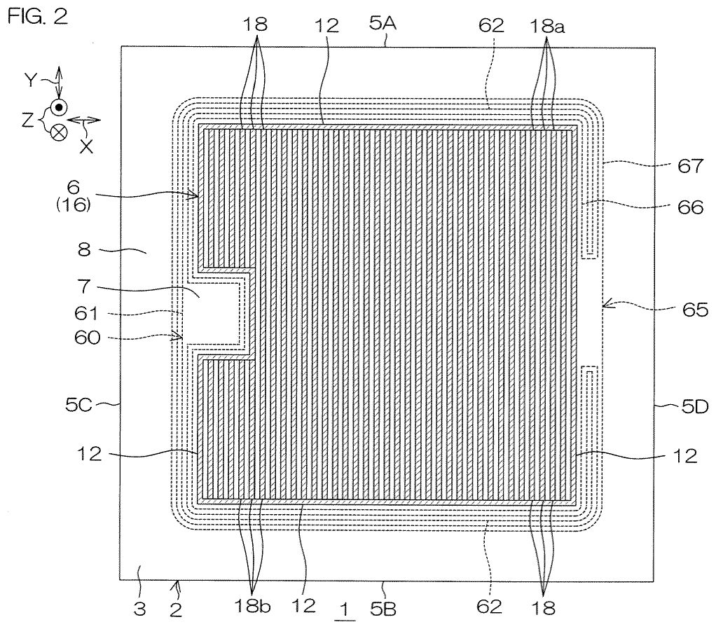

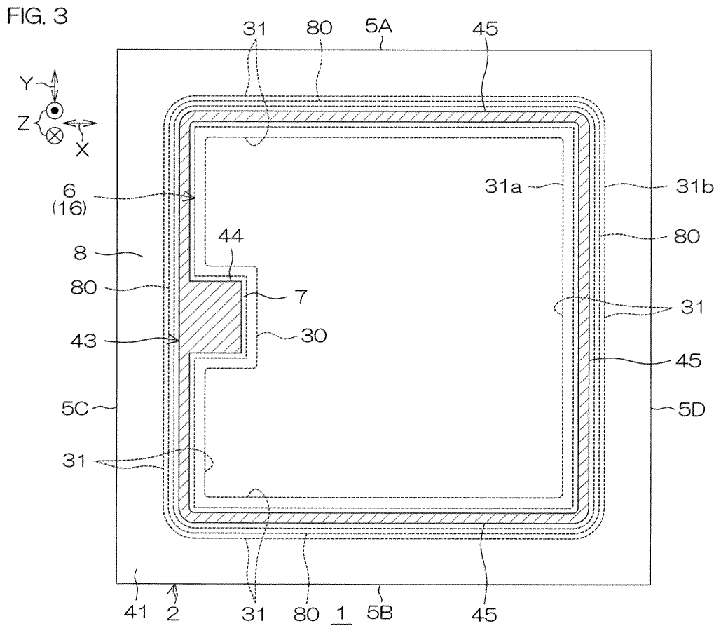

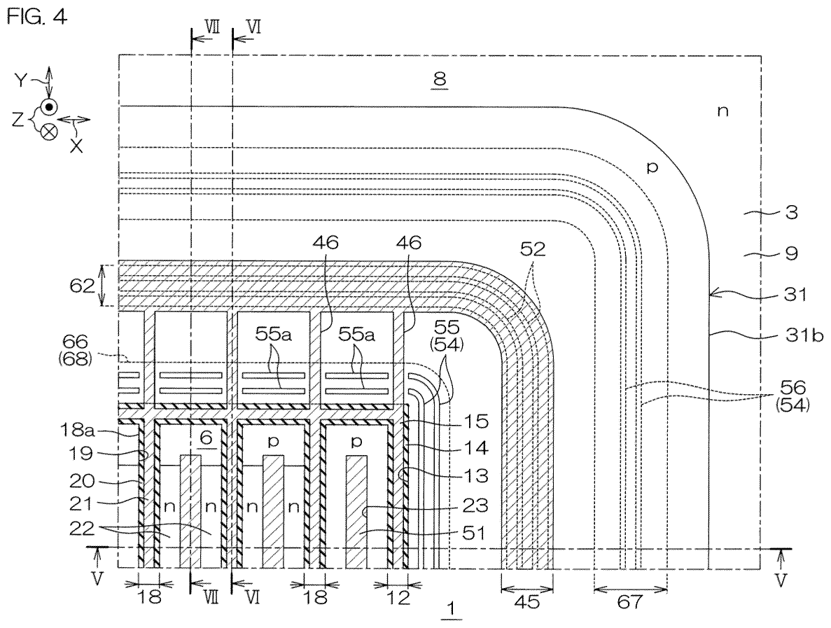

FIG. 1 is a plan view showing a semiconductor device 1 according to an embodiment. FIG. 2 is a plan view showing a layout example within a first main surface 3. FIG. 3 is a plan view showing a layout example of a well region 31, a gate pad wiring 44, a gate line wiring 45, and a cathode region 80. FIG. 4 is a plan view showing an essential portion of a chip 2.

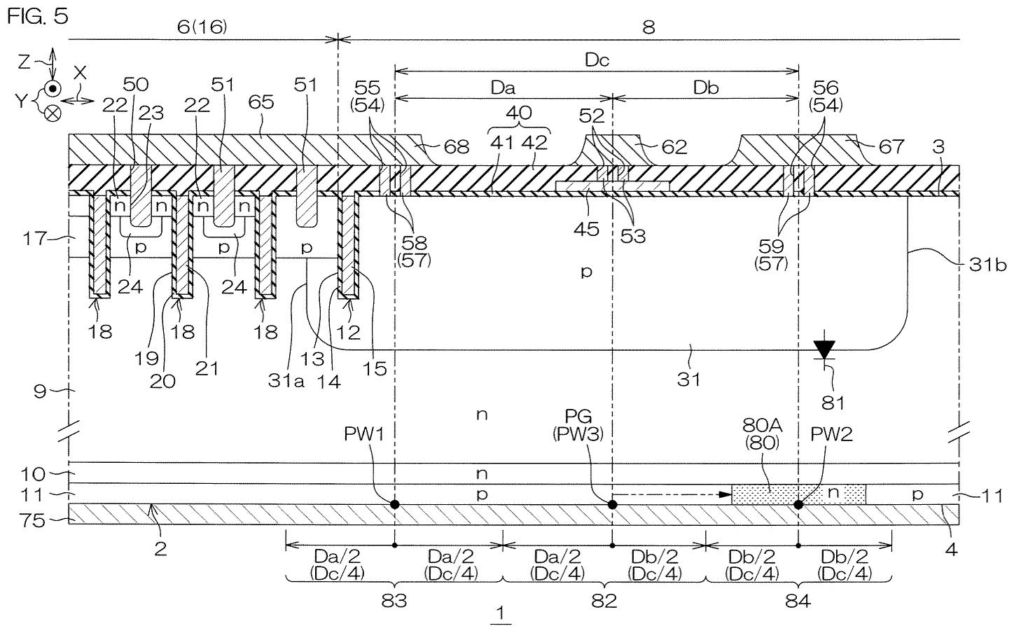

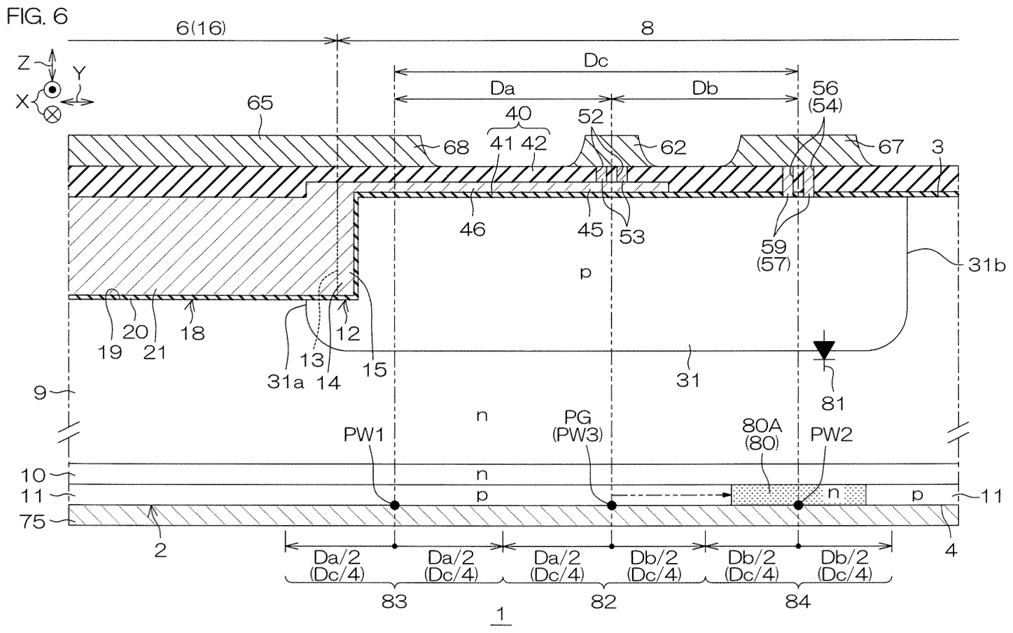

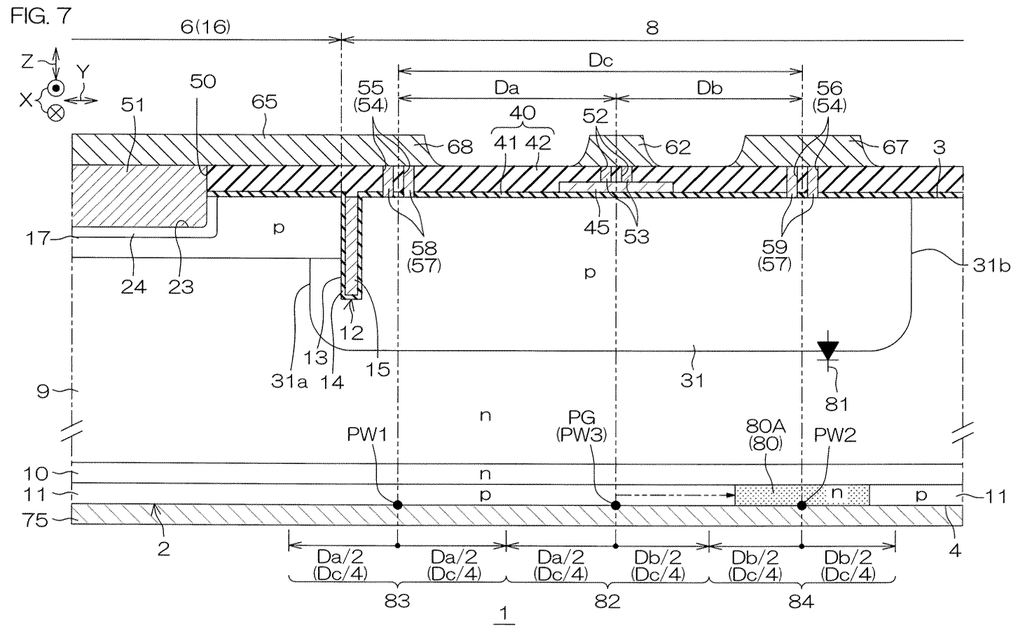

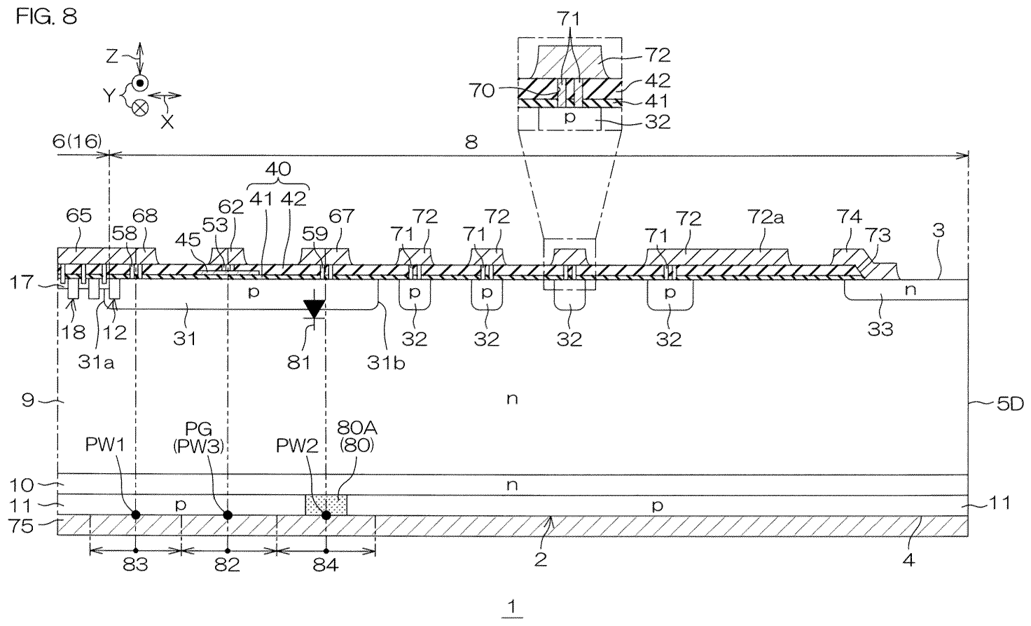

FIG. 5 is a cross-sectional view showing a cross-sectional structure taken along line V-V in FIG. 4 with the cathode region 80A according to the first layout example. FIG. 6 is a cross-sectional view showing a cross-sectional structure taken along line VI-VI in FIG. 4 with the cathode region 80A according to the first layout example. FIG. 7 is a cross-sectional view showing a cross-sectional structure taken along line VII-VII in FIG. 4 with the cathode region 80A according to the first layout example. FIG. 8 is a cross-sectional view showing a cross-sectional structure of a peripheral edge portion of the chip 2 with the cathode region 80A according to the first layout example.

With reference to FIGS. 1 to 8, the semiconductor device 1 is an RC-IGBT (Reverse Conducting-Insulated Gate Bipolar Transistor) semiconductor device (semiconductor switching device) that has an RC-IGBT with an IGBT and a diode integrated therein. The diode is a freewheeling diode for the IGBT.

The semiconductor device 1 includes a hexahedral (specifically, rectangular parallelepiped) chip 2. The chip 2 may be referred to as “semiconductor chip.” The chip 2, in this embodiment, has a single layered structure that consists of a silicon single crystal substrate (semiconductor substrate). The chip 2 has a first main surface 3 on one side, a second main surface 4 on the other side, and first to fourth side surfaces 5A to 5D that connect the first main surface 3 and the second main surface 4.

The first main surface 3 and the second main surface 4 are each formed in a quadrilateral shape in a plan view in their normal directions Z (hereinafter simply referred to as “plan view”). The normal directions Z also serve as the thickness direction of the chip 2. The first side surface 5A and the second side surface 5B extend in a first direction X along the first main surface 3 and oppose each other in a second direction Y that intersects with (specifically, orthogonal to) the first direction X. The third side surface 5C and the fourth side surface 5D extend in the second direction Y and oppose each other in the first direction X.

The semiconductor device 1 includes an IGBT region 6 that is provided in an inner portion of the first main surface 3. The IGBT region 6 has an IGBT structure and may be referred to as “active region.” The IGBT region 6, in this embodiment, is formed in a polygonal shape that has four sides in parallel with the first to fourth side surfaces 5A to 5D in a plan view. Specifically, the IGBT region 6 has a recessed portion that is recessed from a central portion of the side along the third side surface 5C toward the fourth side surface 5D in a plan view. The recessed portion is recessed in a polygonal shape (quadrilateral shape in this embodiment) in a plan view.

The semiconductor device 1 includes a pad region 7 that is provided in a region defined by the recessed portion of the IGBT region 6 in the first main surface 3. The pad region 7 is set in a polygonal shape (quadrilateral shape in this embodiment) in a plan view. The semiconductor device 1 includes an outer peripheral region 8 that is provided in a peripheral edge portion of the chip 2. The outer peripheral region 8 is provided in an annular shape (quadrilateral annular shape) that extends along the first to fourth side surfaces 5A to 5D so as to surround the IGBT region 6. The outer peripheral region 8 is connected to the pad region 7 at a portion that extends along the third side surface 5C.

The semiconductor device 1 includes an n-type (first conductivity type) drift region 9 that is formed within the chip 2. The drift region 9 is formed within the entire chip 2. In this embodiment, the chip 2 consists of an n-type semiconductor substrate (n-type semiconductor chip), and the drift region 9 is formed utilizing the chip 2.

The semiconductor device 1 includes an n-type buffer region 10 that is formed in a surface layer portion of the second main surface 4. The buffer region 10, in this embodiment, is formed in a layer shape that extends along the second main surface 4 over the entire second main surface 4. The buffer region 10 is exposed through the first to fourth side surfaces 5A to 5D. The buffer region 10 has an n-type impurity concentration that is higher than that of the drift region 9. The buffer region 10 may be, or may not be provided, and an embodiment without such a buffer region 10 may be employed.

The semiconductor device 1 includes a p-type (second conductivity type) collector region 11 that is formed in the surface layer portion of the second main surface 4. The collector region 11 is formed in a surface layer portion of the buffer region 10 toward the second main surface 4. The collector region 11, in this embodiment, is formed in a layer shape that extends along the second main surface 4 over the entire second main surface 4. The collector region 11 is exposed through the second main surface 4 and the first to fourth side surfaces 5A to 5D.

The semiconductor device 1 includes a trench isolation structure 12 that is formed in the first main surface 3 so as to define the IGBT region 6. The trench isolation structure 12 is arranged to be applied with a gate potential. The trench isolation structure 12 surrounds the IGBT region 6 and thus isolates the IGBT region 6 from the outer peripheral region 8 and the pad region 7. The trench isolation structure 12, in this embodiment, is formed in a polygonal annular shape that has four sides in parallel with the first to fourth side surfaces 5A to 5D in a plan view.

The trench isolation structure 12 may have a width of not less than 0.5 μm and not more than 5 μm. The width of the trench isolation structure 12 is defined as a width in a direction orthogonal to the direction in which the trench isolation structure 12 extends. The width of the trench isolation structure 12 is preferably not less than 1 μm and not more than 2.5 μm. The trench isolation structure 12 may have a depth of not less than 1 μm and not more than 20 μm. The depth of the trench isolation structure 12 is preferably not less than 4 μm and not more than 10 μm.

The trench isolation structure 12 includes an isolation trench 13, an isolation insulating film 14, and an isolation embedded electrode 15. The isolation trench 13 is bored down from the first main surface 3 toward the second main surface 4 and defines a wall surface for the trench isolation structure 12. The isolation insulating film 14 is formed in a film along the wall surface of the isolation trench 13 and defines a recessed space within the isolation trench 13.

The isolation insulating film 14 may include at least one of a silicon oxide film, a silicon nitride film, a silicon oxynitride film, and an aluminum oxide film. The isolation insulating film 14 preferably has a single layered structure that consists of a single insulating film. It is particularly preferable that the isolation insulating film 14 includes a silicon oxide film that is composed of oxides of the chip 2.

The isolation embedded electrode 15 is embedded in the isolation trench 13 with the isolation insulating film 14 therebetween. The isolation embedded electrode 15, in this embodiment, is composed of conductive polysilicon. The isolation embedded electrode 15 is arranged to be applied with a gate potential.

The semiconductor device 1 includes an IGBT structure 16 that is formed in the IGBT region 6. The IGBT structure 16 may be referred to as “FET ((Field Effect Transistor) structure.” The IGBT structure 16 includes a p-type base region 17 that is formed in a surface layer portion of the first main surface 3 within the IGBT region 6. The base region 17 may be referred to as “body region” or “channel region.” The base region 17 is formed shallower than the trench isolation structure 12, with the bottom portion positioned nearer the first main surface 3 than the bottom wall of the trench isolation structure 12. The base region 17 extends in a layer shape along the first main surface 3, in contact with the inner peripheral wall of the trench isolation structure 12.

The IGBT structure 16 includes a plurality of trench gate structures 18 that are formed in the first main surface 3 within the IGBT region 6. The plurality of trench gate structures 18 are arranged to be applied with a gate potential. The plurality of trench gate structures 18 penetrate the base region 17 into the drift region 9. The plurality of trench gate structures 18 are arranged at intervals in the first direction X and each formed in a band shape that extends in the second direction Y in a plan view. That is, the plurality of trench gate structures 18 are arranged in a stripe pattern that extends in the second direction Y.

The plurality of trench gate structures 18 each have a first end portion 18A on one end (nearer the first side surface 5A) and a second end portion 18B on the other end (nearer the second side surface 5B) in the longitudinal direction (the second direction Y). The first end portion 18A and the second end portion 18B are mechanically and electrically connected to the trench isolation structure 12.

That is, the plurality of trench gate structures 18 form one ladder-shaped trench gate structure 18 with the trench isolation structure 12. The connection portion between the trench isolation structure 12 and the trench gate structure 18 may be considered as part of the trench isolation structure 12 or as part of the trench gate structure 18.

The plurality of trench gate structures 18 may be arranged at intervals of not less than 0.5 μm and not more than 5 μm in the first direction X. The intervals between the plurality of trench gate structures 18 are preferably not less than 1 μm and not more than 3 μm. Each trench gate structure 18 may have a width of not less than 0.5 μm and not more than 5 μm. The width of each trench gate structure 18 is defined as a width in a direction orthogonal to the direction in which each trench gate structure 18 extends.

The width of each trench gate structure 18 is preferably not less than 1 μm and not more than 2.5 μm. The width of each trench gate structure 18 is preferably approximately equal to the width of the trench isolation structure 12. Each trench gate structure 18 may have a depth of not less than 1 μm and not more than 20 μm. The depth of each trench gate structure 18 is preferably not less than 4 μm and not more than 10 μm. The depth of each trench gate structure 18 is preferably approximately equal to the depth of the trench isolation structure 12.

The configuration of one of the trench gate structures 18 will hereinafter be described. The trench gate structure 18 includes a gate trench 19, a gate insulating film 20, and a gate embedded electrode 21. The gate trench 19 is bored down from the first main surface 3 toward the second main surface 4 and defines a wall surface for the trench gate structure 18. The gate trench 19, in this embodiment, is in communication with the isolation trench 13 at the longitudinal end portions (the first end portion 18A and the second end portion 18B). Specifically, the side wall of the gate trench 19 is in communication with the side wall of the isolation trench 13 and the bottom wall of the gate trench 19 is in communication with the bottom wall of the isolation trench 13.

The gate insulating film 20 is formed in a film along the wall surface of the gate trench 19 and defines a recessed space within the gate trench 19. The gate insulating film 20 may include at least one of a silicon oxide film, a silicon nitride film, a silicon oxynitride film, and an aluminum oxide film.

The gate insulating film 20 preferably has a single layered structure that consists of a single insulating film. It is particularly preferable that the gate insulating film 20 includes a silicon oxide film that is composed of oxides of the chip 2. The gate insulating film 20, in this embodiment, is composed of the same insulating film as the isolation insulating film 14. The gate insulating film 20 is s connected to the isolation insulating film 14 within the communication portion between the isolation trench 13 and the gate trench 19.

The gate embedded electrode 21 fills the gate trench 19 with the gate insulating film 20 therebetween. The gate embedded electrode 21, in this embodiment, is composed of conductive polysilicon. The gate embedded electrode 21 is arranged to be applied with a gate potential. The gate embedded electrode 21 is connected to the isolation embedded electrode 15 within the communication portion between the isolation trench 13 and the gate trench 19.

The IGBT structure 16 includes a plurality of n-type emitter regions 22 that are formed in regions along the plurality of trench gate structures 18 in a surface layer portion of the base region 17. The plurality of emitter regions 22 each have an n-type impurity concentration that is higher than that of the drift region 9.

The plurality of emitter regions 22 are arranged on either side of each of the plurality of trench gate structures 18 and each formed in a band shape that extends along the plurality of trench gate structures 18 in a plan view. The emitter regions 22 are preferably not formed in regions that are defined by the end portions (the first end portion 18a/the second end portion 18b) of the trench isolation structure 12 and the trench gate structure 18 in the surface layer portion of the base region 17.

The IGBT structure 16 includes a plurality of contact holes 23 that are formed in the first main surface 3 so as to expose the emitter regions 22 therethrough. The plurality of contact holes 23 are each formed in a region between a pair of adjacent ones of the plurality of trench gate structures 18 at intervals from the plurality of trench gate structures 18. The plurality of contact holes 23 may each be formed in a tapered shape in which the opening width tapers from the opening toward the bottom wall.

The plurality of contact holes 23, in this embodiment, penetrate the emitter regions 22 into the base region 17. As a matter of course, the plurality of contact holes 23 may be spaced apart from the bottom portions of the emitter regions 22 toward the first main surface 3 so as not to enter the base region 17. The plurality of contact holes 23 are each formed in a band shape that extends along the plurality of trench gate structure 18 in a plan view. The plurality of contact holes 23 are shorter than the plurality of trench gate structures 18 in the longitudinal direction (the second direction Y).

The IGBT structure 16 includes a plurality of p-type contact regions 24 that are formed in regions different from the plurality of emitter regions 22 in a surface layer portion of the base region 17. The plurality of contact regions 24 have a p-type impurity concentration that is higher than that of the base region 17. The plurality of contact regions 24 are each formed in a band shape that extends along the corresponding contact hole 23 in a plan view. The bottom portions of the plurality of contact regions 24 are each formed in a region between the bottom wall of the corresponding contact hole 23 and the bottom portion of the base region 17.

The semiconductor device 1 includes a p-type pad well region 30 that is formed in the surface layer portion of the first main surface 3 within the pad region 7 so as to define the IGBT region 6 (see FIG. 3). The pad well region 30 may be referred to as “pad anode region.” The pad well region 30, in this embodiment, has a p-type impurity concentration that is higher than that of the base region 17. As a matter of course, the pad well region 30 may have a p-type impurity concentration that is lower than that of the base region 17.

The pad well region 30 is formed in the pad region 7 at an interval from the peripheral edge of the chip 2 toward the IGBT region 6. The pad well region 30 is formed in a polygonal shape (quadrilateral shape in this embodiment) that conforms to the pad region 7 in a plan view.

The pad well region 30 is in contact with the trench isolation structure 12, though not specifically shown in a cross-sectional view. The pad well region 30 is formed deeper than the base region 17. Specifically, the pad well region 30 is formed deeper than the trench isolation structure 12 (the plurality of trench gate structures 18).

The pad well region 30 has a portion that covers the bottom wall of the trench isolation structure 12. The pad well region 30 has a peripheral edge portion that is drawn out from the pad region 7 into the IGBT region 6. The peripheral edge portion of the pad well region 30 has a portion that covers the bottom walls of the plurality of trench gate structures 18 across the trench isolation structure 12.

The peripheral edge portion of the pad well region 30 covers the side wall of the trench isolation structure 12 and the side walls of the plurality of trench gate structures 18 within the IGBT region 6 and is connected to the base region 17 in the surface layer portion of the first main surface 3. That is, the pad well region 30 is electrically connected to the base region 17 and the plurality of emitter regions 22 within the IGBT region 6.

The semiconductor device 1 includes a p-type well region 31 that is formed in the surface layer portion of the first main surface 3 within the outer peripheral region 8 so as to define the IGBT region 6. The well region 31 may be referred to as “anode region.” The well region 31, in this embodiment, has a p-type impurity concentration that is higher than that of the base region 17. As a matter of course, the well region 31 may have a p-type impurity concentration that is lower than that of the base region 17. The well region 31 preferably has a p-type impurity concentration that is approximately equal to that of the pad well region 30.

The well region 31 is formed at an interval from the peripheral edge of the chip 2 toward the IGBT region 6. The well region 31 is formed in a layer shape that extends along the first main surface 3 and exposed through the first main surface 3. The well region 31 is formed in a band shape that extends along the IGBT region 6 in a plan view. Specifically, the well region 31 is formed in an annular shape that surrounds the IGBT region 6 in a plan view and has four sides in parallel with the peripheral edge of the chip 2. The well region 31 has an inner edge 31a that is nearer the IGBT region 6 and an outer edge 31b that is nearer the peripheral edge of the chip 2.

The well region 31 is formed integrally with the pad well region 30 in a portion that extends along the third side surface 5C. That is, the well region 31 integrally includes the pad well region 30 that is drawn out of the outer peripheral region 8 toward the pad region 7. The width of the well region 31 may be not less than 10 μm and not more than 100 μm. The width of the well region 31 is preferably not less than 40 μm and not more than 80 μm.

The well region 31 is formed deeper than the base region 17. Specifically, the well region 31 is formed deeper than the trench isolation structure 12 (the plurality of trench gate structures 18). The well region 31 is in contact with the trench isolation structure 12. The well region 31 has a portion that covers the bottom wall of the trench isolation structure 12. The inner edge 31a of the well region 31 is drawn out from the outer peripheral region 8 into the IGBT region 6 and thereby is positioned within the IGBT region 6.

The well region 31 has a portion that covers the bottom walls of the plurality of trench gate structures 18 across the trench isolation structure 12. The well region 31 covers the side wall of the trench isolation structure 12 and the side walls of the plurality of trench gate structures 18 within the IGBT region 6 and is connected to the base region 17 in the surface layer portion of the first main surface 3. That is, the inner edge 31a of the well region 31 is electrically connected to the base region 17 and the emitter regions 22 within the IGBT region 6.

The semiconductor device 1 includes at least one p-type field region 32 (a plurality of p-type field regions 32 in this embodiment) that is formed in the surface layer portion of the first main surface 3 within the outer peripheral region 8. Any number of field regions 32 may be provided, and the number may be not fewer than one and not more than twenty. The number of field regions 32 is typically not fewer than three and not more than ten.

The plurality of field regions 32 may have a p-type impurity concentration that is higher than that of the base region 17. The plurality of field regions 32 may have a p-type impurity concentration that is higher than that of the well region 31. As a matter of course, the plurality of field regions 32 may have a p-type impurity concentration that is approximately equal to that of the well region 31. The plurality of field regions 32 are formed in an electrically floated state.

The plurality of field regions 32 are formed in regions between the peripheral edge of the chip 2 and the well region 31 at intervals from the peripheral edge of the chip 2 and the well region 31. The plurality of field regions 32 are each formed in a band shape that extends along the well region 31 in a plan view. The plurality of field regions 32, in this embodiment, are each formed in an annular shape (quadrilateral annular shape) that surrounds the well region 31 in a plan view.

The plurality of field regions 32 are preferably formed deeper than the base region 17. The plurality of field regions 32 are preferably formed shallower than the well region 31. The plurality of field regions 32 are preferably formed shallower than the well region 31 by, for example, a depth of not less than 0.1 μm and not more than 1 μm (preferably not more than 0.5 μm) with respect to the depth of the bottom portion of the well region 31.

The plurality of field regions 32 are preferably formed with a constant depth. The plurality of field regions 32 are preferably arranged so as to have a gradually increasing interval therebetween toward the peripheral edge of the chip 2. The plurality of field regions 32 each preferably have a width that is smaller than the width of the well region 31. The outermost one of the plurality of field regions 32 is preferably formed wider than the other field regions 32.

The width of each field region 32 may be not less than 1 μm and not more than 50 μm. The width of each field region 32 may be set to a value that belongs to one of the following ranges: not less than 1 μm and not more than 2.5 μm, not less than 2.5 μm and not more than 5 μm, not less than 5 μm and not more than 7.5 μm, not less than 7.5 μm and not more than 10 μm, not less than 10 μm and not more than 20 μm, not less than 20 μm and not more than 30 μm, not less than 30 μm and not more than 40 μm, and not less than 40 μm and not more than 50 μm. The width of each field region 32 is preferably not less than 10 μm and not more than 30 μm.

The semiconductor device 1 includes an n-type channel stop region 33 that is formed in the surface layer portion of the first main surface 3 at an interval from the plurality of field regions 32 toward the peripheral edge of the chip 2 within the outer peripheral region 8. The channel stop region 33 has an n-type impurity concentration that is higher than that of the drift region 9. The channel stop region 33 may be exposed through the first to fourth side surfaces 5A to 5D.

The channel stop region 33 is formed in a band shape that extends along the peripheral edge of the chip 2 in a plan view. The channel stop region 33, in this embodiment, is formed in an annular shape (quadrilateral annular shape) that surrounds the plurality of field regions 32 in a plan view. The channel stop region 33 is formed in an electrically floated state.

The semiconductor device 1 includes an insulating film 40 that selectively covers the first main surface 3. The insulating film 40, in this embodiment, has a laminated structure that includes a main surface insulating film 41 (first insulating film) and an interlayer insulating film 42 (second insulating film).

The main surface insulating film 41 selectively covers the first main surface 3 within the IGBT region 6, the outer peripheral region 8, and the pad region 7. The main surface insulating film 41 may include at least one of a silicon oxide film, a silicon nitride film, a silicon oxynitride film, and an aluminum oxide film. The main surface insulating film 41 preferably has a single layered structure that consists of a single insulating film.

It is particularly preferable that the main surface insulating film 41 includes a silicon oxide film that is composed of oxides of the chip 2. The main surface insulating film 41, in this embodiment, is composed of the same insulating film as the gate insulating film 20. The main surface insulating film 41 covers the first main surface 3 so as to expose the trench isolation structure 12 and the plurality of trench gate structures 18 therethrough.

Specifically, the main surface insulating film 41 is connected to the isolation insulating film 14 and the gate insulating film 20 and exposes the isolation embedded electrode 15 and the gate embedded electrode 21 therethrough. The main surface insulating film 41 covers the pad well region 30, the well region 31, the field regions 32, and the channel stop region 33 within the pad region 7 and the outer peripheral region 8.

The interlayer insulating film 42 covers the main surface insulating film 41. The interlayer insulating film 42 is thicker than the main surface insulating film 41. The interlayer insulating film 42 may have a single layered structure that consists of a single insulating film or a laminated structure that includes a plurality of insulating films. The interlayer insulating film 42 may include at least one of a silicon oxide film, a silicon nitride film, a silicon oxynitride film, and an aluminum oxide film. The interlayer insulating layer 42 may include at least one of an NSG (Non-doped Silicate Glass) film, a PSG (Phosphor Silicate Glass) film, and a BPSG (Boron Phosphor Silicate Glass) film as an example of the silicon oxide film.

The interlayer insulating film 42 covers the main surface insulating film 41 within the IGBT region 6, the outer peripheral region 8, and the pad region 7. The interlayer insulating film 42 covers the main surface insulating film 41, the trench isolation structure 12, and the plurality of trench gate structures 18 within the IGBT region 6. The interlayer insulating film 42 covers the pad well region 30, the well region 31, the field regions 32, and the channel stop region 33 with the main surface insulating film 41 therebetween within the pad region 7 and the outer peripheral region 8.

The semiconductor device 1 includes a gate wiring 43 that is arranged in a film within the insulating film 40. The gate wiring 43, in this embodiment, is composed of a conductive polysilicon film. The gate wiring 43, in this embodiment, includes a gate pad wiring 44, a gate line wiring 45, and a plurality of gate connection wirings 46. The gate line wiring 45 may be referred to as “gate finger wiring.”

The gate pad wiring 44 is arranged within a portion of the insulating film 40 that covers the pad region 7, and opposes the pad well region 30 in the thickness direction of the chip 2. Specifically, the gate pad wiring 44 is arranged in a film on the main surface insulating film 41 and covered with the interlayer insulating film 42. The gate pad wiring 44 is formed in a polygonal shape (quadrilateral shape in this embodiment) that conforms to the pad region 7 in a plan view. The peripheral edge portion of the gate pad wiring 44 may be positioned within the pad region 7.

As a matter of course, the peripheral edge portion of the gate pad wiring 44 may be drawn out from the pad region 7 toward the IGBT region 6. In this case, the peripheral edge portion of the gate pad wiring 44 may be drawn from on the main surface insulating film 41 onto a portion of the trench isolation structure 12 that defines the pad region 7 and connected to the isolation embedded electrode 15. Also, the peripheral edge portion of the gate pad wiring 44 may cover a part (the first end portion 18A or the second end portion 18B) of the plurality of trench gate structures 18 and connected to a plurality of gate embedded electrodes 21.

The gate line wiring 45 is arranged within a portion of the insulating film 40 that covers the outer peripheral region 8, and opposes the well region 31 in the thickness direction of the chip 2. Specifically, the gate line wiring 45 is arranged in a film on the main surface insulating film 41 and covered with the interlayer insulating film 42. The gate line wiring 45, in this embodiment, is arranged only in a portion of the insulating film 40 that covers the well region 31.

That is, the gate line wiring 45 opposes an inner portion of the well region 31 at an interval from the outer edge 31B and the inner edge 31a of the well region 31 in a plan view. Also, the entire gate line wiring 45 opposes the well region 31 with the main surface insulating film 41 therebetween. The gate line wiring 45 extends in a band shape that extends along the well region 31 in a plan view. The gate line wiring 45 preferably defines the IGBT region 6 in a plurality of directions in a plan view.

The gate line wiring 45, in this embodiment, is formed in a band shape that extends along the first to fourth side surfaces 5A to 5D, and defines the IGBT region 6 in four directions. The gate line wiring 45 may be formed in an endless band shape or an ended band shape so as to surround the IGBT region 6. The gate line wiring 45, in this embodiment, is formed in an annular shape (specifically, quadrilateral annular shape) that surrounds the IGBT region 6.

The gate line wiring 45 is formed integrally with the gate pad wiring 44 in a portion that extends along the third side surface 5C. That is, the gate line wiring 45 integrally includes the gate pad wiring 44 that is drawn out from the outer peripheral region 8 to the pad region 7. The gate line wiring 45 has a width that is smaller than the width of the well region 31. The width of the gate line wiring 45 may be not less than 10 μm and not more than 100 μm. The width of the gate line wiring 45 is preferably not less than 15 μm and not more than 60 μm.

The plurality of gate connection wirings 46 are arranged within the insulating film 40 so as to electrically connect the gate line wiring 45 to the plurality of gate trench structures 18. The plurality of gate connection wirings 46 are drawn out from a portion of the gate line wiring 45 that extends along the first side surface 5A toward the first end portions 18A of the plurality of trench gate structures 18. Also, the plurality of gate connection wirings 46 are drawn out from a portion of the gate line wiring 45 that extends along the second side surface 5B toward the second end portions 18B of the plurality of trench gate structures 18.

The plurality of gate connection wirings 46 are arranged at intervals along the gate line wiring 45 nearer the first side surface 5A and drawn out toward the trench isolation structure 12. The plurality of gate connection wirings 46 are preferably arranged at regular intervals in the first direction X. The plurality of gate connection wirings 46 are drawn out from on the main surface insulating film 41 onto the trench isolation structure 12 nearer the first side surface 5A and connected to the isolation embedded electrode 15. The plurality of gate connection wirings 46, in this embodiment, cover the respective first end portions 18A of the plurality of trench gate structures 18 and are connected to the plurality of gate embedded electrodes 21.

Similarly, the plurality of gate connection wirings 46 are arranged at intervals along the gate line wiring 45 nearer the second side surface 5B and drawn out toward the trench isolation structure 22. The plurality of gate connection wirings 46 are preferably arranged at regular intervals in the first direction X. The plurality of gate connection wirings 46 are drawn out from on the main surface insulating film 41 onto the trench isolation structure 12 nearer the second side surface 5B and connected to the isolation embedded electrode 15.

The plurality of gate connection wirings 46, in this embodiment, cover the respective second end portions 18B of the plurality of trench gate structures 18 and are connected to the plurality of gate embedded electrodes 21. The gate wiring 43, in this embodiment, is formed of the same conductive material as the isolation embedded electrode 15 and the gate embedded electrodes 21 and consists of a drawer portion that is drawn out from the isolation embedded electrode 15 and the plurality of gate embedded electrodes 21 onto the main surface insulating film 41.

The semiconductor device 1 has a plurality of emitter openings 50 that expose the plurality of emitter regions 22 therethrough in a portion of the insulating film 40 that covers the IGBT region 6. The plurality of emitter openings 50 are formed in one-to-one correspondence with respect to the plurality of contact holes 23 and in communication, respectively, with the corresponding contact holes 23. The plurality of emitter openings 50 are each formed in a band shape that extends along the corresponding contact hole 23 in a plan view.

The semiconductor device 1 includes a plurality of emitter connection electrodes 51 that are embedded in the insulating film 40 so as to be electrically connected to the plurality of emitter regions 22. The plurality of emitter connection electrodes 51 are embedded through the plurality of emitter openings 50. The plurality of emitter connection electrodes 51 enter the plurality of contact holes 23 through the plurality of emitter openings 50 and are electrically connected to the emitter regions 22 and the contact regions 24.

Each emitter connection electrode 51 may include at least one of a Ti-based metal film, a W-based metal film, an Al-based metal film, and a Cu-based metal film. Each emitter connection electrode 51, in this embodiment, has a laminated structure that includes a Ti-based metal film and a W-based metal film.

The Ti-based metal may include at least one of a pure Ti film (Ti film with a purity of not less than 99%) and a Ti alloy film (the same hereinafter). The Ti alloy film may be a TiN film (the same hereinafter). The W-based metal may include at least one of a pure W film (W film with a purity of not less than 99%) and a W alloy film (the same hereinafter).

The Al-based metal may include at least one of a pure Al film (Al film with a purity of not less than 99%) and an Al alloy film (the same hereinafter). The Al alloy film may contain at least one of AlCu alloy, AlSi alloy, and AlSiCu alloy (the same hereinafter). The Cu-based metal may include at least one of a pure Cu film (Cu film with a purity of not less than 99%) and a Cu alloy film (the same hereinafter).

The semiconductor device 1 includes at least one gate opening 52 (a plurality of gate openings 52 in this embodiment) that selectively exposes the gate line wiring 45 therethrough in a portion of the insulating film 40 that covers the gate line wiring 45. While the plurality of gate openings 52 are formed in this embodiment, a single gate opening 52 may be formed.

The plurality of gate openings 52 expose an inner portion of the gate line wiring 45 therethrough at intervals from the inner edge and the outer edge of the gate line wiring 45. The plurality of gate openings 52 are formed at intervals with respect to each other from nearer the IGBT region 6 toward the peripheral edge of the chip 2 and each extend in a band shape along the gate line wiring 45. Each gate opening 52 may be formed in an endless band shape or an ended band shape so as to surround the IGBT region 6. Each gate opening 52, in this embodiment, is formed in an annular shape (specifically, quadrilateral annular shape) that surrounds the IGBT region 6.

The semiconductor device 1 may include at least one gate opening 52 (a plurality of gate openings 52 in this embodiment) that selectively exposes the gate pad wiring 44 therethrough in a portion of the insulating film 40 that covers the gate pad wiring 44, though not specifically shown.

The semiconductor device 1 includes at least one gate connection electrode 53 (a plurality of gate connection electrodes 53 in this embodiment) that is embedded in the insulating film 40 so as to be electrically connected to the gate line wiring 45. Each gate connection electrode 53 may include at least one of a Ti-based metal film, a W-based metal film, an Al-based metal film, and a Cu-based metal film. Each gate connection electrode 53, in this embodiment, has a laminated structure that includes a Ti-based metal film and a W-based metal film.

The plurality of gate connection electrodes 53 are embedded in one-to-one correspondence, respectively, through the plurality of gate openings 52. The plurality of gate connection electrodes 53 are electrically connected to the gate line wiring 45 within the corresponding gate openings 52. In a case in which a gate opening 52 that exposes the gate pad wiring 44 therethrough is formed in the insulating film 40, a gate connection electrode 53 that is to be electrically connected to the gate pad wiring 44 may be formed within the gate opening 52.

The semiconductor device 1 includes a plurality of well openings 54 that selectively expose the well region 31 therethrough in a portion of the insulating film 40 that covers the outer peripheral region 8. The plurality of well openings 54 include at least one first well opening 55 (a plurality of first well openings 55 in this embodiment) and at least one second well opening 56 (a plurality of second well openings 56 in this embodiment). While the plurality of first well openings 55 are formed in this embodiment, a single first well opening 55 may be formed. Also, while the plurality of second well openings 56 are formed, a single second well opening 56 may be formed.

The plurality of first well openings 55 expose the well region 31 therethrough nearer the IGBT region 6. Specifically, the plurality of first well openings 55 are formed at intervals from a middle portion in the width direction of the well region 31 toward the inner edge 31a of the well region 31 and selectively expose regions of the well region 31 nearer the inner edge 31a therethrough. More specifically, the plurality of first well openings 55 are formed at intervals from the gate line wiring 45 toward the inner edge 31a of the well region 31 and selectively expose inner edge portions of the well region 31 therethrough.

The plurality of first well openings 55 are formed at intervals with respect to each other from nearer the IGBT region 6 toward the peripheral edge of the chip 2 and each extend in a band shape along the well region 31. Each first well opening 55 has a portion that extends in the first direction X along the well region 31 and a portion that extends in the second direction Y along the well region 31.

Each first well opening 55 includes a plurality of segment opening portions 55a that are formed at intervals so as to expose regions between the plurality of gate connection wirings 46 therethrough in portions that extend in the first direction X. In other words, the plurality of segment opening portions 55a are formed at intervals from the plurality of gate connection wirings 46 so as not to expose the plurality of gate connection wirings 46 therethrough.

The plurality of segment opening portions 55a are arranged in regions that are surrounded by the trench isolation structure 12 (the plurality of trench gate structures 18), the gate line wiring 45, and the plurality of gate connection wirings 46. The plurality of segment opening portions 55a are each formed in a band shape that extends in the first direction X.

The plurality of second well openings 56 expose the well region 31 therethrough nearer the peripheral edge of the chip 2. Specifically, the plurality of second well openings 56 are formed at intervals from a middle portion in the width direction of the well region 31 toward the outer edge 31b of the well region 31 and selectively expose regions of the well region 31 nearer the outer edge 31b therethrough. More specifically, the plurality of second well openings 56 are formed at intervals from the gate line wiring 45 toward the outer edge 31b of the well region 31 and selectively expose outer edge portions of the well region 31 therethrough.

The plurality of second well openings 56 are formed at intervals with respect to each other from nearer the IGBT region 6 toward the peripheral edge of the chip 2 and each extend in a band shape along the well region 31. Each second well opening 56 may be formed in an endless band shape or an ended band shape so as to surround the IGBT region 6. Each second well opening 56, in this embodiment, is formed in an annular shape (specifically, quadrilateral annular shape) that surrounds the IGBT region 6.

The semiconductor device 1 includes a plurality of well connection electrodes 57 that are embedded in the insulating film 40 so as to be electrically connected to the well region 31. Each well connection electrode 57 may include at least one of a Ti-based metal film, a W-based metal film, an Al-based metal film, and a Cu-based metal film. Each well connection electrode 57, in this embodiment, has a laminated structure that includes a Ti-based metal film and a W-based metal film.

The plurality of well connection electrodes 57 include at least one first well connection electrode 58 (a plurality of first well connection electrodes 58 in this embodiment) and at least one second well connection electrode 59 (a plurality of second well connection electrodes 59 in this embodiment). While the plurality of first well connection electrodes 58 are formed in this embodiment, a single first well connection electrode 58 may be formed. Also, while the plurality of second well connection electrodes 59 are formed, a single second well connection electrode 59 may be formed.

The plurality of first well connection electrodes 58 are connected to the well region 31 nearer the inner edge 31a of the well region 31 (nearer the IGBT region 6). Specifically, the plurality of first well connection electrodes 58 are embedded in one-to-one correspondence, respectively, through the plurality of first well openings 55.

That is, the plurality of first well connection electrodes 58 are formed at intervals from a middle portion in the width direction of the well region 31 toward the inner edge 31a of the well region 31 and electrically connected to regions of the well region 31 nearer the inner edge 31a. Also, the plurality of first well connection electrodes 58 are formed in regions at intervals from the gate line wiring 45 toward the inner edge 31a of the well region 31 and electrically connected to inner edge portions of the well region 31.

The plurality of second well connection electrodes 59 are connected to the well region 31 nearer the outer edge 31b of the well region 31 (nearer the peripheral edge of the chip 2). Specifically, the plurality of second well connection electrodes 59 are embedded in one-to-one correspondence, respectively, through the plurality of second well openings 56.

That is, the plurality of second well connection electrodes 59 are formed at intervals from a middle portion in the width direction of the well region 31 toward the outer edge 31b of the well region 31 and electrically connected to regions of the well region 31 nearer the outer edge 31b. Also, the plurality of second well connection electrodes 59 are formed in regions at intervals from the gate line wiring 45 toward the outer edge 31b of the well region 31 and electrically connected to outer edge portions of the well region 31.

The semiconductor device 1 includes a gate electrode 60 that is arranged on the insulating film 40. The gate electrode 60 is composed of conductive material that is different from that of the gate wiring 43. The gate electrode 60, in this embodiment, is composed of a metal film and has a resistance value that is lower than that of the gate wiring 43. The gate electrode 60 may be referred to as “gate metal.” The gate electrode 60 may include at least one of a Ti-based metal film, a W-based metal film, an Al-based metal film, and a Cu-based metal film. The gate electrode 60, in this embodiment, has a laminated structure that includes a Ti-based metal film and an Al-based metal film.

The gate electrode 60 includes a gate pad electrode 61 and a gate line electrode 62. The gate line electrode 62 may be referred to as “gate finger electrode.” The gate pad electrode 61 is arranged on a portion of the insulating film 40 that covers the gate pad wiring 44. The gate pad electrode 61, in this embodiment, is formed in a polygonal shape (quadrilateral shape in this embodiment) that conforms to the pad region 7 in a plan view.

The gate pad electrode 61 opposes the gate pad wiring 44 with a portion (the interlayer insulating film 42) of the insulating film 40 therebetween in the thickness direction of the chip 2. The gate pad electrode 61 opposes the pad well region 30 with the insulating film 40 and the gate pad wiring 44 therebetween in the thickness direction of the chip 2. In a case in which the gate connection electrodes 53 are connected to the gate pad wiring 44, the gate pad electrode 61 may be electrically connected to the gate connection electrodes 53 via the gate pad wiring 44.

The gate pad electrode 61 may have a planar area that is not smaller than the planar area of the pad region 7 or may have a planar area that is smaller than the planar area of the pad region 7. The gate pad electrode 61 may have a planar area that is not smaller than the planar area of the gate pad wiring 44 or may have a planar area that is smaller than the planar area of the gate pad wiring 44.

The gate pad electrode 61 may be formed at intervals from the plurality of trench gate structures 18 in a plan view or may oppose the plurality of trench gate structures 18 with the insulating film 40 therebetween. The gate pad electrode 61 may be formed at an interval from the trench isolation structure 12 in a plan view or may oppose the trench isolation structure 12 with the insulating film 40 therebetween.

The gate line electrode 62 is arranged on a portion of the insulating film 40 that covers the gate line wiring 45. The gate line electrode 62 is formed integrally with the gate pad electrode 61 and drawn out in a band shape from the gate pad electrode 61 onto the insulating film 40. The gate line electrode 62, in this embodiment, is drawn out from the gate pad electrode 61 to a region between the first well connection electrodes 58 and the second well connection electrodes 59 on the insulating film 40.

The gate line electrode 62 is arranged at intervals from the first well connection electrodes 58 and the second well connection electrodes 59 and covers the plurality of gate connection electrodes 53. That is, the gate line electrode 62 is arranged at intervals from the first well connection electrodes 58 toward the outer edge 31b of the well region 31 (toward the peripheral edge of the chip 2) and arranged at intervals from the second well connection electrodes 59 toward the inner edge 31a of the well region 31 (toward the IGBT region 6). The gate line electrode 62 is electrically connected to the gate line wiring 45 via the plurality of gate connection electrodes 53.

The gate line electrode 62 opposes the gate line wiring 45 with a portion of the insulating film 40 therebetween in the thickness direction of the chip 2. The gate line electrode 62 opposes the well region 31 with the insulating film 40 and the gate line wiring 45 therebetween in the thickness direction of the chip 2. The gate line electrode 62 has a width that is smaller than the width of the well region 31. The gate line electrode 62 preferably has a width that is smaller than the width of the gate line wiring 45. As a matter of course, the gate line electrode 62 may have a width that is not smaller than the width of the gate line wiring 45.

The gate line electrode 62 extends in a band shape along the gate line wiring 45 in a plan view. The gate line electrode 62 preferably defines the IGBT region 6 in a plurality of directions in a plan view. The gate line electrode 62, in this embodiment, is formed in a band shape that extends along the first to fourth side surfaces 5A to 5D, and defines the IGBT region 6 in four directions.

The gate line electrode 62 may be formed in an endless band shape or an ended band shape so as to surround the IGBT region 6. The gate line electrode 62, in this embodiment, is formed in an annular shape (specifically, quadrilateral annular shape) that surrounds the IGBT region 6, and has a pair of open ends 63 in a portion that extends along the fourth side surface 5D.

The semiconductor device 1 includes an emitter electrode 65 that is arranged on the insulating layer 40 at an interval from the gate electrode 60. The emitter electrode 65 is composed of conductive material that is different from that of the gate wiring 43. The emitter electrode 65, in this embodiment, is composed of a metal film and has a resistance value that is lower than that of the gate wiring 43. The emitter electrode 65 may be referred to as “emitter metal.”

The emitter electrode 65 may include at least one of a Ti-based metal film, a W-based metal film, an Al-based metal film, and a Cu-based metal film. The emitter electrode 65, in this embodiment, has a laminated structure that includes a Ti-based metal film and an Al-based metal film. That is, the emitter electrode 65 is formed of the same material as the gate electrode 60.

The emitter electrode 65 includes an emitter pad electrode 65 and an emitter line electrode 67. The emitter line electrode 67 may be referred to as “emitter finger electrode.” The emitter pad electrode 66 is arranged on a portion of the insulating film 40 that covers the IGBT region 6. Specifically, the emitter pad electrode 66 is arranged at intervals from the gate pad electrode 61 and the gate line electrode 62 and formed in a polygonal shape that has a recessed portion recessed along the gate pad electrode 61 in a plan view.

The emitter pad electrode 66 collectively covers the plurality of trench gate structures 18 and the plurality of emitter connection electrodes 51. The emitter pad electrode 66 opposes the plurality of trench gate structures 18 with the insulating film 40 therebetween and is electrically connected to the plurality of emitter regions 22 via the plurality of emitter connection electrodes 51. The emitter pad electrode 66 has an emitter drawer portion 68 that is drawn out from the IGBT region 6 across a region immediately above the trench isolation structure 12 to the outer peripheral region 8 so as to oppose the well region 31 in the thickness direction of the chip 2.

The emitter drawer portion 68 (the emitter pad electrode 66) covers a region nearer the inner edge 31a of the well region 31 with respect to a middle portion in the width direction of the well region 31. The emitter drawer portion 68 specifically covers an inner edge portion of the well region 31 at an interval from the gate line electrode 62 toward the IGBT region 6 and collectively covers the plurality of first well connection electrodes 58. This causes the emitter pad electrode 66 to be electrically connected to the inner edge portion of the well region 31 via the plurality of first well connection electrodes 58.

The emitter line electrode 67 is formed integrally with the emitter pad electrode 66 and drawn out from the emitter pad electrode 66 onto the insulating film 40. Specifically, the emitter line electrode 67 passes through a region between the pair of open ends 63 of the gate line electrode 62 on the insulating film 40 to be drawn out in a band shape from the emitter pad electrode 66 to the outer peripheral region 8.

The emitter line electrode 67 is routed on a portion of the insulating film 40 that covers the well region 31. That is, the emitter line electrode 67 opposes the well region 31 with the insulating film 40 therebetween in the thickness direction of the chip 2. The emitter line electrode 67 is arranged at an interval from the gate line electrode 62 toward the outer edge 31b of the well region 31 (toward the peripheral edge of the chip 2) so as to cover the plurality of second well connection electrodes 59. This causes the emitter line electrode 67 to be electrically connected to the outer edge portion of the well region 31 via the plurality of second well connection electrodes 59.

The emitter line electrode 67 extends in a band shape along the outer edge 31b of the well region 31 in a plan view. The emitter line electrode 67 preferably defines the IGBT region 6 in a plurality of directions in a plan view. The emitter line electrode 67, in this embodiment, is formed in a band shape that extends along the first to fourth side surfaces 5A to 5D, and defines the IGBT region 6 in four directions. The well region 31 may be formed in an endless band shape or an ended band shape so as to surround the IGBT region 6. The emitter line electrode 67, in this embodiment, is formed in an annular shape (specifically, quadrilateral annular shape) that surrounds the IGBT region 6.

The emitter line electrode 67 preferably has a width that is smaller than the width of the well region 31. The emitter line electrode 67 is preferably arranged at an interval from a region immediately above the innermost one of the field regions 32 toward the well region 31. The emitter line electrode 67 is preferably arranged at an interval from a region immediately above the outer edge 31b of the well region 31 toward the inner edge 31a of the well region 31. The region of the emitter line electrode 67 other than a portion that is connected to the emitter pad electrode 66 is preferably arranged only in a region that opposes the well region 31.

The insulating film 40 includes at least one field opening 70 (a plurality of field openings 70 in this embodiment) that selectively exposes each field region 32 therethrough within the outer peripheral region 8. The plurality of field openings 70 expose the corresponding field region 32 in many-to-one correspondence. As a matter of course, a single field opening 70 may expose the corresponding field region 32 in one-to-one correspondence. The plurality of field openings 70 are each formed in a band shape that extends along the corresponding field region 32. The plurality of field openings 70, in this embodiment, are each formed in an annular shape (quadrilateral annular shape) that extends along the corresponding field region 32.

The semiconductor device 1 includes at least one field connection electrode 71 (a plurality of field connection electrodes 71 in this embodiment) that is embedded in the insulating film 40 so as to be electrically connected to the corresponding field region 32. Each field connection electrode 71 may include at least one of a Ti-based metal film, a W-based metal film, an Al-based metal film, and a Cu-based metal film. Each field connection electrode 71, in this embodiment, has a laminated structure that includes a Ti-based metal film and a W-based metal film.

The plurality of field connection electrodes 71 are embedded in one-to-one correspondence, respectively, through the plurality of field openings 70. The plurality of field connection electrodes 71 are electrically connected to the corresponding field region 32 within the corresponding field openings 70. The plurality of field connection electrodes 71, in this embodiment, are formed in an electrically floated state.

The semiconductor device 1 includes a plurality of field electrodes 72 that are formed on the insulating film 40 within the outer peripheral region 8. The plurality of field electrodes 72 may each include at least one of a Ti-based metal film, a W-based metal film, an Al-based metal film, and a Cu-based metal film. The plurality of field electrodes 72 may each have a laminated structure that includes a Ti-based metal film and an Al-based metal film. The plurality of field electrodes 72 are formed in an electrically floated state.

The plurality of field electrodes 72 are formed in one-to-one correspondence with respect to the corresponding field region 32. Each field electrode 72 collectively covers the corresponding plurality of field connection electrodes 71. Each field electrode 72 is electrically connected to the corresponding field region 32 via the corresponding plurality of field connection electrodes 71.

The plurality of field electrodes 72 are each formed in a band shape that extends along the corresponding field region 32. The plurality of field electrodes 72, in this embodiment, are each formed in an annular shape (quadrilateral annular shape) that extends along the corresponding field region 32. The outermost one of the field electrodes 72 includes a field drawer portion 72a that is drawn out toward the peripheral edge of the chip 2, and may be formed wider than the other field electrodes 72.

The insulating film 40 includes a channel stop opening 73 that exposes the channel stop region 33 therethrough within the outer peripheral region 8. The channel stop opening 73 is formed in a band shape that extends along the channel stop region 33. The channel stop opening 73, in this embodiment, is formed in an annular shape (quadrilateral annular shape) that extends along the channel stop region 33, and is in communication with the peripheral edge of the chip 2.

The semiconductor device 1 includes a channel stop electrode 74 that is formed on the insulating film 40 within the outer peripheral region 8. The channel stop electrode 74 may include at least one of a Ti-based metal film, a W-based metal film, an Al-based metal film, and a Cu-based metal film. The channel stop electrode 74 may have a laminated structure that includes a Ti-based metal film and an Al-based metal film. The channel stop electrode 74 are formed in an electrically floated state.

The channel stop electrode 74 is formed in a band shape that extends along the channel stop region 33. The channel stop electrode 74, in this embodiment, is formed in an annular shape (quadrilateral annular shape) that extends along the channel stop region 33. The channel stop electrode 74 enters the channel stop opening 73 from on the insulating film 40 and is electrically connected to the channel stop region 33. The channel stop electrode 74 may be formed at an interval from the peripheral edge of the chip 2 toward the IGBT region 6 so as to expose a peripheral edge portion of the first main surface 3 (the channel stop region 33) therethrough.

The semiconductor device 1 includes a collector electrode 75 that covers the second main surface 4. The collector electrode 75 is electrically connected to a collector region 11 that is exposed through the second main surface 4. The collector electrode 75 is in ohmic contact with the collector region 11. The collector electrode 75 may cover the entire second main surface 4 so as to be continuous with the peripheral edge of the chip 2 (the first to fourth side surfaces 5A to 5D).

The collector electrode 75 may have a single film structure or a laminated structure that includes at least one of a Ti film, an Ni film, a Pd film, an Au film, an Ag film, and an Al film. The collector electrode 75 preferably includes a Ti film that directly covers at least the second main surface 4. The collector electrode 75 may have a laminated structure that includes, for example, a Ti film, an Ni film, a Pd film, and an Au film laminated in this order from the second main surface 4.

With reference to FIGS. 5 to 7, the semiconductor device 1 includes an n-type cathode region 80 that is formed in the surface layer portion of the second main surface 4 within the outer peripheral region 8. A basic structure of the cathode region 80 will hereinafter be described. The cathode region 80 has an n-type impurity concentration that is higher than the p-type impurity concentration of the collector region 11, in which the conductivity type of a part of the collector region 11 is replaced from p-type to n-type. The cathode region 80 preferably has an n-type impurity concentration that is higher than that of the drift region 9 (the buffer region 10).

The cathode region 80 is formed in a layer shape along the second main surface 4 and exposed through the second main surface 4. The cathode region 80 penetrates the collector region 11 so as to be connected to the buffer region 10. The cathode region 80 is in ohmic contact with the above-described collector electrode 75. The cathode region 80, in this embodiment, is arranged at a location that opposes the well region 31 in the thickness direction of the chip 2, and forms a diode 81 with the well region 31. The diode 81 is formed as a freewheeling diode for the IGBT structure 16.

The cathode region 80 may be formed in an endless band shape or an ended band shape so as to surround the IGBT region 6 in a plan view. The cathode region 80, in this embodiment, is formed in an annular shape (specifically, quadrilateral annular shape) that surrounds the IGBT region 6. The cathode region 80 is arranged such that the well region 31 has a portion that opposes the cathode region 80 and a portion that opposes the collector region 11 in the thickness direction of the chip 2.

That is, the cathode region 80 is formed narrower than the well region 31 so as not to oppose the entire well region 31 in the thickness direction of the chip 2. The width of the cathode region 80 may be not less than 5 μm and not more than 90 μm. The width of the cathode region 80 is preferably not less than 10 μm and not more than 40 μm.

The cathode region 80 is preferably formed at an interval from the base region 17 toward the peripheral edge of the second main surface 4 so as not to oppose the base region 17 in at least the thickness direction of the chip 2. The cathode region 80 is preferably formed at intervals from the plurality of trench gate structures 18 toward the peripheral edge of the second main surface 4 so as not to oppose the plurality of trench gate structures 18 in the thickness direction of the chip 2. It is particularly preferable that the cathode region 80 is formed at an interval from the trench isolation structure 12 toward the peripheral edge of the second main surface 4 so as not to oppose the trench isolation structure 12 in the thickness direction of the chip 2.

That is, the cathode region 80 is preferably formed at an interval from the IGBT region 6 toward the peripheral edge of the chip 2 so as not to oppose the IGBT region 6 in the thickness direction of the chip 2. That is, the cathode region 80 is preferably not formed in the IGBT region 6, but only in the outer peripheral region 8. In this case, the IGBT region 6 can have reduced electrical impact on the diode 81 and, at the same time, the diode 81 can have reduced electrical impact on the IGBT region 6.

The ratio of the planar area of the cathode region 80 to the planar area of the second main surface 4 is preferably not less than 0.1% and not more than 10%. The ratio of the planar area of the cathode region 80 may belong to one of the following ranges: not less than 0.1% and not more than 1%, not less than 1% and not more than 2%, not less than 2% and not more than 4%, not less than 4% and not more than 6%, not less than 6% and not more than 8%, and not less than 8% and not more than 10%.

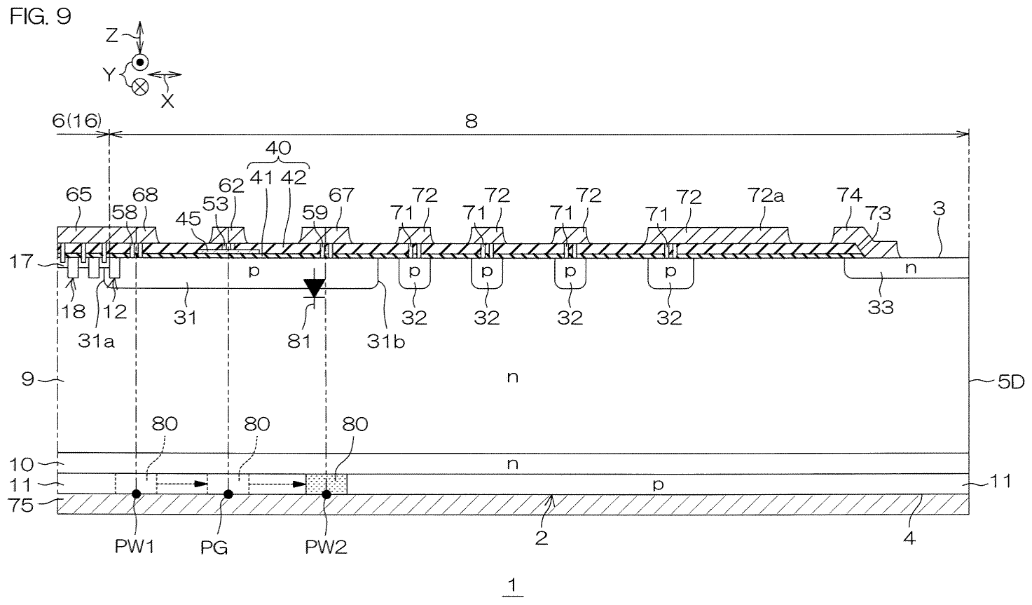

When a forward voltage VF for the diode 81 is applied between the emitter electrode 65 and the collector electrode 75, a forward current IF flows through the diode 81. The forward current IF, in this embodiment, flows from the first well connection electrodes 58 and the second well connection electrodes 59 into the cathode region 80. The electrical characteristics of the diode 81 during the forward operation vary depending on the arrangement location of the cathode region 80. The relationship between the arrangement location of the cathode region 80 and the electrical characteristics of the diode 81 will hereinafter be described with reference to FIGS. 9 to 16.

FIG. 9 is a cross-sectional view for illustrating an arrangement location of the cathode region 80. With reference to FIG. 9, a gate reference position PG, a first well reference position PW1, and a second well reference position PW2 are set as an arrangement location of the cathode region 80. The gate reference position PG is immediately below the center of the gate line electrode 62. The gate reference position PG, in this embodiment, is also immediately below the center of the gate line wiring 45. The gate reference position PG may therefore be set immediately below the center of the gate line electrode 62 or immediately below the center of the gate line wiring 45.

The first well reference position PW1 is immediately below one of the first well connection electrodes 58. In a case in which a single first well connection electrode 58 is formed, the first well reference position PW1 is immediately below the center of the single first well connection electrode 58. In a case in which a plurality of first well connection electrodes 58 are formed, the first well reference position PW1 is immediately below the middle between the innermost first well connection electrode 58 that is arranged nearer the IGBT region 6 and the outermost first well connection electrode 58 that is arranged nearer the peripheral edge of the chip 2.

The second well reference position PW2 is immediately below one of the second well connection electrodes 59. In a case in which a single second well connection electrode 59 is formed, the second well reference position PW2 is immediately below the center of the single second well connection electrode 59. In a case in which a plurality of second well connection electrodes 59 are formed, the second well reference position PW2 is immediately below the middle between the innermost second well connection electrode 59 that is arranged nearer the IGBT region 6 and the outermost second well connection electrode 59 that is arranged nearer the peripheral edge of the chip 2.

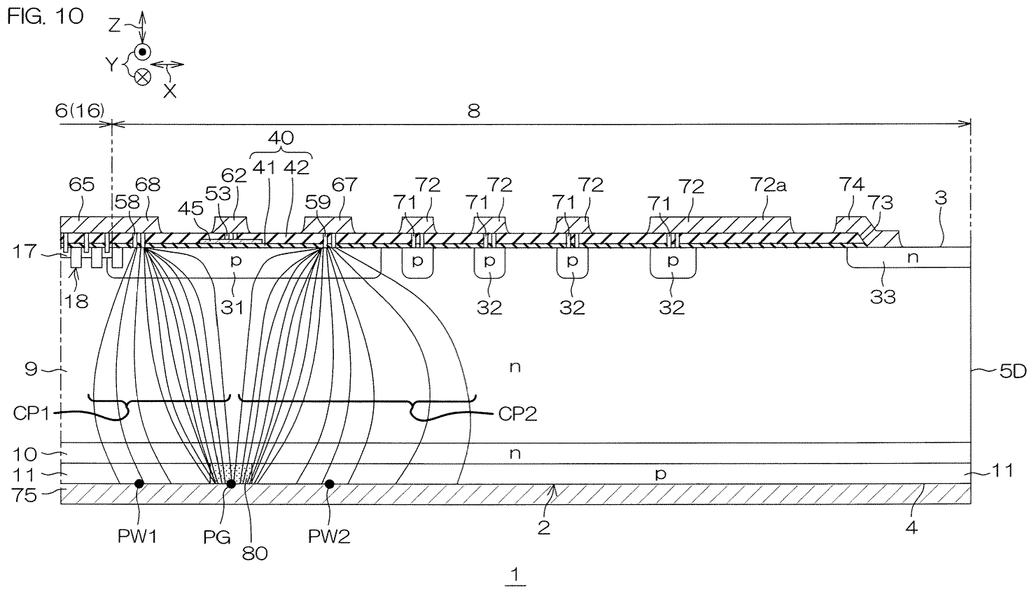

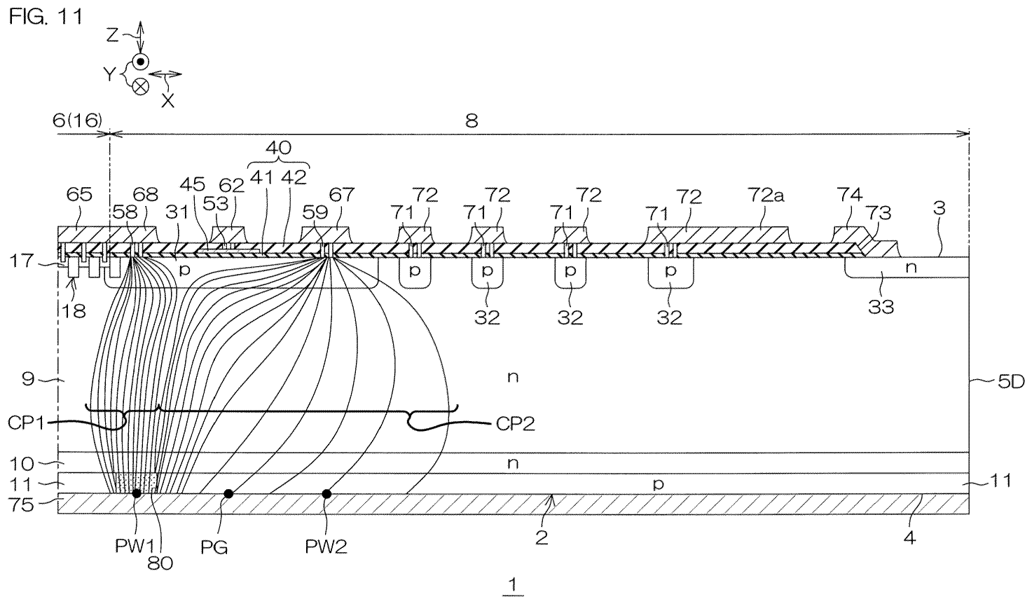

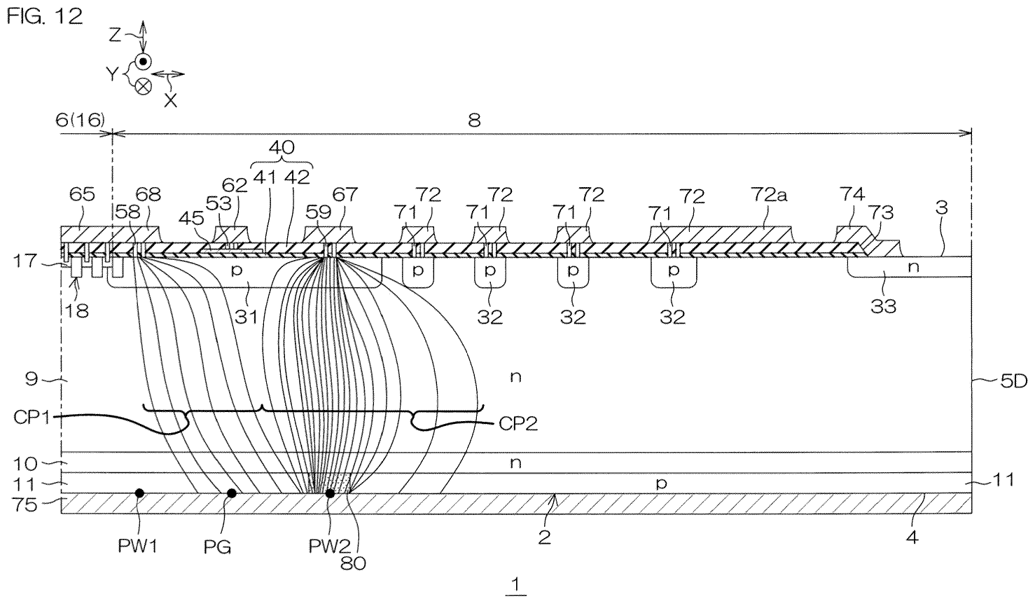

FIG. 10 is a cross-sectional view showing the current density of a forward current IF in a case in which the cathode region 80 is arranged at the gate reference position PG. FIG. 11 is a cross-sectional view showing the current density of a forward current IF in a case in which the cathode region 80 is arranged at the first well reference position PW1. FIG. 12 is a cross-sectional view showing the current density of a forward current IF in a case in which the cathode region 80 is arranged at the second well reference position PW2. In FIGS. 10 to 12, the width of the cathode region 80 is fixed to a constant value (10 μm in this embodiment).

With reference to FIG. 10, in a case in which the cathode region 80 is arranged at the gate reference position PG, a first current pathway CP1 is formed from the plurality of first well connection electrodes 58 through a region immediately below the gate line electrode 62 to the cathode region 80, and a second current pathway CP2 is formed from the plurality of second well connection electrodes 59 through a region immediately below the gate line electrode 62 to the cathode region 80. The current density of the forward current IF is sparse in both the first current pathway CP1 and the second current pathway CP2.

With reference to FIG. 11, in a case in which the cathode region 80 is arranged at the first well reference position PW1, a first current pathway CP1 is formed from the plurality of first well connection electrodes 58 directly to the cathode region 80, and a second current pathway CP2 is formed from the plurality of second well connection electrodes 59 through a region immediately below the gate line electrode 62 to the cathode region 80. The current density of the forward current IF is dense in the first current pathway CP1, while sparse in the second current pathway CP2.

With reference to FIG. 12, in a case in which the cathode region 80 is arranged at the second well reference position PW2, a first current pathway CP1 is formed from the plurality of first well connection electrodes 58 through a region immediately below the gate line electrode 62 to the cathode region 80, and a second current pathway CP2 is formed from the plurality of second well connection electrodes 59 directly to the cathode region 80. The current density of the forward current IF is sparse in the first current pathway CP1, while dense in the second current pathway CP2.

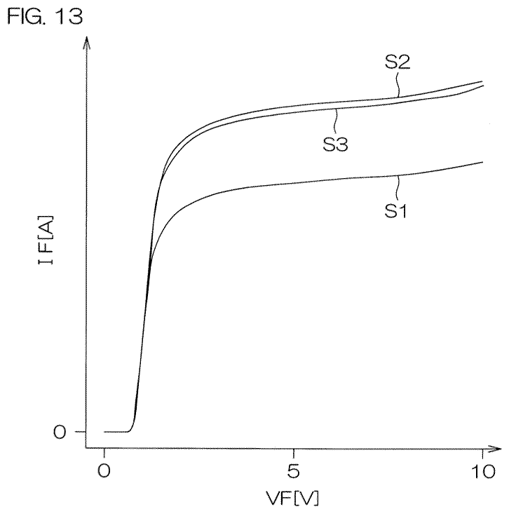

FIG. 13 is a graph summarizing the relationship between the forward current IF and the forward voltage VF for FIGS. 10 to 12. In FIG. 13, the vertical axis represents the forward current IF [A] and the horizontal axis represents the forward voltage VF [V]. FIG. 13 shows a first characteristic S1, a second characteristic S2, and a third characteristic S3.

The first characteristic S1 is for the case in which the cathode region 80 is arranged at the gate reference position PG. The second characteristic S2 is for the case in which the cathode region 80 is arranged at the first well reference position PW1. The third characteristic S3 is for the case in which the cathode region 80 is arranged at the second well reference position PW2.

The forward current IF according to the second characteristic S2 is larger than the forward current IF according to the first characteristic S1. The forward current IF according to the third characteristic S3 is also larger than the forward current IF according to the first characteristic S1. Also, the forward current IF according to the second characteristic S2 is larger than the forward current IF according to the third characteristic S3. From this, it has been found that the cathode region 80 is preferably arranged avoiding the gate reference position PG in order to suppress the current bypass pathway. It has also been found that the cathode region 80 is preferably arranged at one or both of the first well reference position PW1 and the second well reference position PW2.

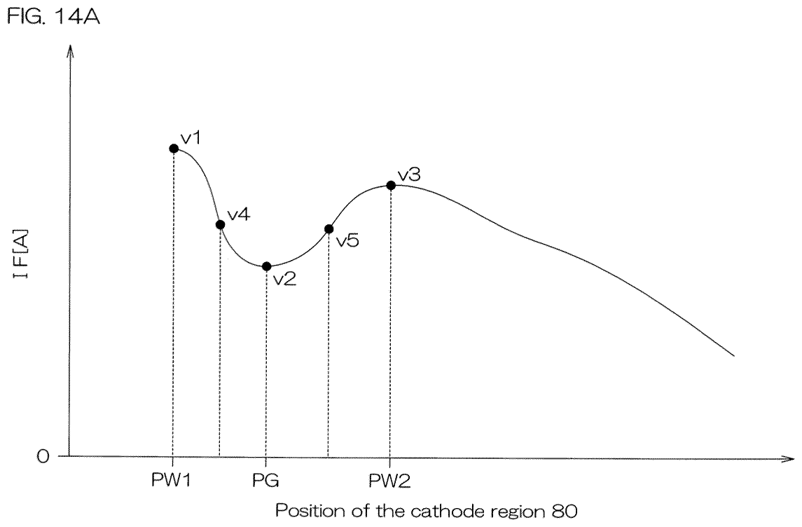

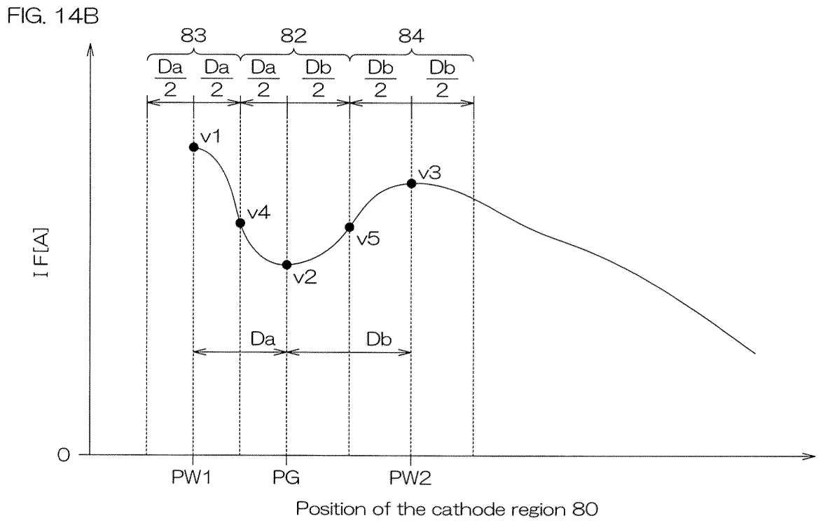

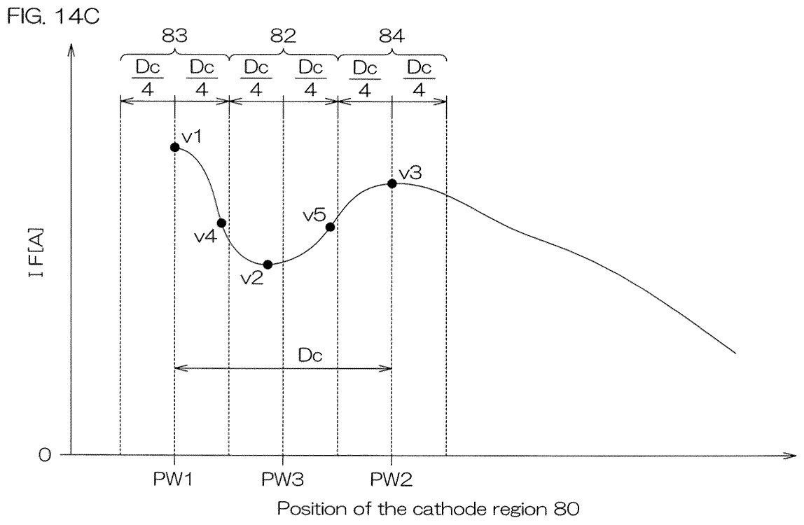

FIG. 14A is a graph showing the relationship between the arrangement location of the cathode region 80 and the forward current IF. In FIG. 14, the vertical axis represents the forward current IF [A] and the horizontal axis represents the position of the cathode region 80. FIG. 14A shows a result of movement of the arrangement location of the cathode region 80 from the first well reference position PW1 toward the peripheral edge of the chip 2. In this embodiment, the arrangement location of the cathode region 80 is moved to a region immediately below the third field region 32 when counted from nearer the well region 31. The width of the cathode region 80 is fixed to a constant value (10 μm in this embodiment).

With reference to FIG. 14A, the forward current IF decreases gradually as the arrangement location of the cathode region 80 is moved from the first well reference position PW1 and approaches the gate reference position PG. The forward current IF increases gradually as the arrangement location of the cathode region 80 is moved from the gate reference position PG and approaches the second well reference position PW2. The forward current IF decreases gradually as the arrangement location of the cathode region 80 is moved from the second well reference position PW2 and approaches the peripheral edge of the chip 2.

When the cathode region 80 is arranged at the first well reference position PW1, the forward current IF takes a first local maximum value v1. When the cathode region 80 is arranged at the gate reference position PG, the forward current IF takes a local minimum value v2. When the cathode region 80 is arranged at the second well reference position PW2, the forward current IF takes a second local maximum value v3.

When the cathode region 80 is arranged in the vicinity of immediately below the middle between the first well reference position PW1 and the gate reference position PG, the forward current IF takes a value in the vicinity of the intermediate value between the first local maximum value v1 and the local minimum value v2. The value in the vicinity of the intermediate value between the first local maximum value v1 and the local minimum value v2 is also a value in the vicinity of a first inflection point v4 between the first local maximum value v1 and the local minimum value v2.

When the cathode region 80 is arranged in the vicinity of immediately below the middle between the second well reference position PW2 and the gate reference position PG, the forward current IF takes a value in the vicinity of the intermediate value between the second local maximum value v3 and the local minimum value v2. The value in the vicinity of the intermediate value between the second local maximum value v3 and the local minimum value v2 is also a value in the vicinity of a second inflection point v5 between the second local maximum value v3 and the local minimum value v2.

Accordingly, it has been found that a prohibited range 82 in which the cathode region 80 is not permitted to be arranged in the vicinity of the gate reference position PG is preferably set on the second main surface 4. It has also been found that a first permitted range 83 in which the cathode region 80 is permitted to be partially or fully arranged in the vicinity of the first well reference position PW1 is preferably set on the second main surface 4. It has also been found that a second permitted range 84 in which the cathode region 80 is permitted to be partially or fully arranged in the vicinity of the second well reference position PW2 is preferably set on the second main surface 4.

FIG. 14B illustrates a first setting example of the prohibited range 82, the first permitted range 83, and the second permitted range 84 based on the result in FIG. 14A. With reference to FIG. 14B, when the cathode region 80 is arranged in a region nearer the first well reference position PW1, the prohibited range 82 and the first permitted range 83 may be set based on a first reference distance Da between the first well reference position PW1 and the gate reference position PG.

In this case, the prohibited range 82 is set within a range that does not exceed one-half of the first reference distance Da with reference to the gate reference position PG. The prohibited range 82 is set nearer the IGBT region 6 with reference to the first well reference position PW1. In this case, the cathode region 80 is arranged at a distance of at least one-half of the first reference distance Da from the gate reference position PG toward the first well reference position PW1.

On the other hand, the first permitted range 83 is set within a range that does not exceed one-half of the first reference distance Da with reference to the first well reference position PW1. The first permitted range 83 is set nearer the IGBT region 6 and the gate reference position PG with reference to the first well reference position PW1. In this case, the cathode region 80 is at least partially arranged within a range of not more than one-half of the first reference distance Da from the first well reference position PW1.

When the cathode region 80 is arranged in a region nearer the second well reference position PW2, the prohibited range 82 and the second permitted range 84 are set based on a second reference distance Db between the second well reference position PW2 and the gate reference position PG.

In this case, the prohibited range 82 is set within a range that does not exceed one-half of the second reference distance Db with reference to the gate reference position PG. The prohibited range 82 is set nearer the second well reference position PW2 with reference to the gate reference position PG. In this case, the cathode region 80 is arranged at a distance of at least one-half of the second reference distance Db from the gate reference position PG toward the second well reference position PW2.

On the other hand, the second permitted range 84 is set within a range that does not exceed one-half of the second reference distance Db with reference to the second well reference position PW2. The second permitted range 84 is set nearer the peripheral edge of the chip 2 and the gate reference position PG with reference to the second well reference position PW2. In this case, the cathode region 80 is at least partially arranged within a range of not more than one-half of the second reference distance Db from the second well reference position PW2.

When the cathode region 80 is arranged in both a region nearer the first well reference position PW1 and a region nearer the second well reference position PW2, the prohibited range 82 is set within a range that does not exceed one-half of the first reference distance Da from the gate reference position PG toward the first well reference position PW1 and within a range that does not exceed one-half of the second reference distance Db from the gate reference position PG toward the second well connection electrode 59.

On the one hand, the first permitted range 83 is set within a range that does not exceed one-half of the first reference distance Da with reference to the first well reference position PW1. The first permitted range 83 is set nearer the IGBT region 6 and the gate reference position PG with reference to the first well reference position PW1. On the other hand, the second permitted range 84 is set within a range that does not exceed one-half of the second reference distance Db with reference to the second well reference position PW2. The second permitted range 84 is set nearer the peripheral edge of the chip 2 and the gate reference position PG with reference to the second well reference position PW2.

The first reference distance Da may be not less than 1 μm and not more than 50 μm. The first reference distance D1 may be set to a value that belongs to one of the following ranges: not less than 1 μm and not more than 5 μm, not less than 5 μm and not more than 10 μm, not less than 10 μm and not more than 15 μm, not less than 15 μm and not more than 20 μm, not less than 20 μm and not more than 25 μm, not less than 25 μm and not more than 30 μm, not less than 30 μm and not more than 35 μm, not less than 35 μm and not more than 40 μm, not less than 40 μm and not more than 45 μm, and not less than 45 μm and not more than 50 μm. The first reference distance Da is preferably not less than 10 μm and not more than 30 μm. It is particularly preferable that the first reference distance Da is not less than 10 μm and not more than 20 μm.

The second reference distance Db may be or may not be smaller than the first reference distance Da. The second reference distance Db, in this embodiment, is larger than the first reference distance Da. The second reference distance Db may be not less than 1 μm and not more than 100 μm. The second reference distance Db may be set to a value that belongs to one of the following ranges: not less than 1 μm and not more than 5 μm, not less than 5 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 60 μm, not less than 60 μm and not more than 70 μm, not less than 70 μm and not more than 80 μm, not less than 80 μm and not more than 90 μm, and not less than 90 μm and not more than 100 μm. The second reference distance Db is preferably not less than 10 μm and not more than 60 μm. It is particularly preferable that the second reference distance Db is not less than 20 μm and not more than 40 μm.

FIG. 14C is a graph for illustrating a second setting example of the prohibited range 82, the first permitted range 83, and the second permitted range 84 based on the result in FIG. 14A. With reference to FIG. 14C, the forward current IF takes a first local maximum value v1 when the cathode region 80 is arranged at the first well reference position PW1. The forward current IF takes a second local maximum value v3 when the cathode region 80 is arranged at the second well reference position PW2. When the cathode region 80 is arranged in the vicinity of an intermediate reference position PW3 immediately below the middle between the first well reference position PW1 and the second well reference position PW2, the forward current IF takes a value in the vicinity of the local minimum value v2.

When the cathode region 80 is arranged in the vicinity of immediately below the middle between the first well reference position PW1 and the intermediate reference position PW3, the forward current IF takes a value in the vicinity of the intermediate value between the first local maximum value v1 and the local minimum value v2 (a value in the vicinity of the first inflection point v4). When the cathode region 80 is arranged in the vicinity of immediately below the middle between the second well reference position PW2 and the intermediate reference position PW3, the forward current IF takes a value in the vicinity of the intermediate value between the second local maximum value v3 and the local minimum value v2 (a value in the vicinity of the second inflection point v5).

Accordingly, the prohibited range 82, the first permitted range 83, and the second permitted range 84 may be set based on a third reference distance Dc between the first well reference position PW1 and the second well reference position PW2. The third reference distance Dc is also the sum of the first reference distance Da and the second reference distance Db shown in FIG. 14 (Dc=Da+Db). That is, in the second setting example, the prohibited range 82, the first permitted range 83, and the second permitted range 84 are set based on the third reference distance Dc without using the first reference distance Da and the second reference distance Db.

In this case, the prohibited range 82 may be set within a range that does not exceed one-fourth of the third reference distance Dc from the intermediate reference position PW3 immediately below the middle between the first well reference position PW1 and the second well reference position PW2. When the cathode region 80 is arranged in a region nearer the first well reference position PW1, the prohibited range 82 is set nearer the first well reference position PW1 with reference to the intermediate reference position PW3. When the cathode region 80 is arranged in a region nearer the second well reference position PW, the prohibited range 82 is set nearer the second well reference position PW2 with reference to the intermediate reference position PW3.

On the one hand, the first permitted range 83 is set within a range that does not exceed one-fourth of the third reference distance Dc with reference to the first well reference position PW1. The first permitted range 83 is set nearer the IGBT region 6 and the gate reference position PG with reference to the first well reference position PW1. On the other hand, the second permitted range 84 is set within a range that does not exceed one-fourth of the third reference distance Dc with reference to the second well reference position PW2. The second permitted range 84 is set nearer the IGBT region 6 and the gate reference position PG with reference to the second well reference position PW2.

As shown in FIGS. 14B and 14C, the cathode region 80 is preferably arranged in a region outside the prohibited range 82. In accordance with the structure, since the current bypass pathway is suppressed in the region between the first well connection electrodes 58 and the second well connection electrodes 59, the forward current IF is inhibited from being reduced.

The cathode region 80, when arranged in a region nearer the first well reference position PW1, is preferably arranged partially or fully within the first permitted range 83. In accordance with the structure, since the current pathway between the first well connection electrodes 58 and the cathode region 80 is shortened, the forward current IF increases. In this case, the cathode region 80 is preferably arranged at the first well reference position PW1. In accordance with the structure, since a current pathway is formed that linearly links the first well connection electrodes 58 and the cathode region 80, the forward current IF can be increased adequately.

The cathode region 80, when arranged in a region nearer the second well reference position PW2, is preferably arranged partially or fully within the second permitted range 84. In accordance with the structure, since the current pathway between the second well connection electrodes 59 and the cathode region 80 is shortened, the forward current IF increases. In this case, the cathode region 80 is preferably arranged at the second well reference position PW2. In accordance with the structure, since a current pathway is formed that linearly links the second well connection electrodes 59 and the cathode region 80, the forward current IF can be increased adequately.

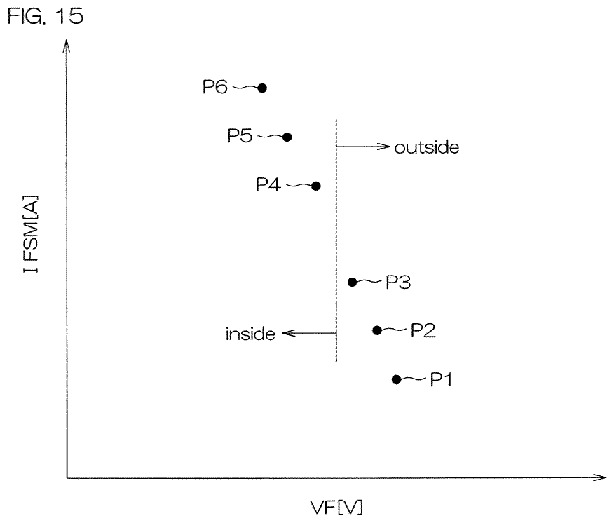

FIG. 15 is a graph showing the relationship between the peak surge current IFSM and the forward voltage VF when the arrangement location of the cathode region 80 is adjusted. In FIG. 15, the vertical axis represents the peak surge current IFSM [A] and the horizontal axis represents the forward voltage VF [V]. The peak surge current IFSM is the peak value of a commercially limited half-wave current (50 Hz or 60 Hz) of one or more cycles allowed without breakdown.

FIG. 15 shows first to sixth plot points P1 to P6. The first to third plot points P1 to P3 show characteristics when the cathode region 80 is arranged at an interval from the well region 31 toward the peripheral edge of the chip 2. The arrangement location of the cathode region 80 is closer to the well region 31 in the order of the first plot point P1, the second plot point P2, and the third plot point P3.

The fourth to sixth plot points P4 to P6 show characteristics when the cathode region 80 is arranged at a position to oppose the well region 31. The arrangement location of the cathode region 80 is closer from nearer the outer edge 31b of the well region 31 to the second well reference position PW2 in the order of the fourth plot point P4, the fifth plot point P5, and the sixth plot point P6. The sixth plot point P6 shows a characteristic when the cathode region 80 is arranged at the second well reference position PW2. As for the first to sixth plot points P1 to P6, the width of the cathode region 80 is fixed to a constant value (10 μm in this embodiment).

With reference to the first to sixth plot points P1 to P6, the peak surge currents IFSM according to the first to third plot points P1 to P3 are larger than the peak surge currents IFSM according to the fourth to sixth plot points P4 to P6. Also, the peak surge current IFSM according to the sixth plot point P6 is larger than the peak surge currents IFSM according to the first to fifth plot points P1 to P5. It has thus been found that the cathode region 80 is preferably arranged in a region immediately below the well region 31. It has also been found that the cathode region 80 is preferably arranged at the second well reference position PW2.

With reference again to FIGS. 5 to 7, the semiconductor device 1 may include, as the cathode region 80, a cathode region 80A according to the first layout example that is formed in view of the above-described measurement results. The cathode region 80A is formed at an interval along the second main surface 4 from the gate reference position PG. Specifically, the cathode region 80A is arranged at an interval along the second main surface 4 from the gate reference position PG toward the second well reference position PW2.

The cathode region 80A is arranged within the second permitted range 84 but not within the prohibited range 82. In this embodiment, the prohibited range 82 and the second permitted range 84 according to the first or second setting example may be applied. The cathode region 80A is arranged at the second well reference position PW2 and opposes the plurality of second well connection electrodes 59 in the thickness direction of the chip 2. The cathode region 80A is arranged at an interval from the gate line electrode 62 toward the second well reference position PW2 so as not to oppose the gate line electrode 62 in the thickness direction of the chip 2.

The cathode region 80A is arranged at an interval from a position immediately below the center of the gate line wiring 45 toward the second well reference position PW2. The cathode region 80A is arranged at intervals from positions immediately below the plurality of gate connection electrodes 53 toward the second well reference position PW2 so as not to oppose the plurality of gate connection electrodes 53 in the thickness direction of the chip 2. The cathode region 80A is arranged at an interval from the gate line wiring 45 toward the second well reference position PW2 so as not to oppose the gate line wiring 45 in the thickness direction of the chip 2.

The cathode region 80A has a width that is smaller than the width of the emitter line electrode 67. As a matter of course, the cathode region 80A may have a width that is not smaller than the width of the emitter line electrode 67. The cathode region 80A is formed at an interval from a position immediately below the outer edge 31b of the well region 31 toward the second well reference position PW2. The cathode region 80A is formed only in a region that opposes the well region 31 in the thickness direction of the chip 2 in the surface layer portion of the second main surface 4.

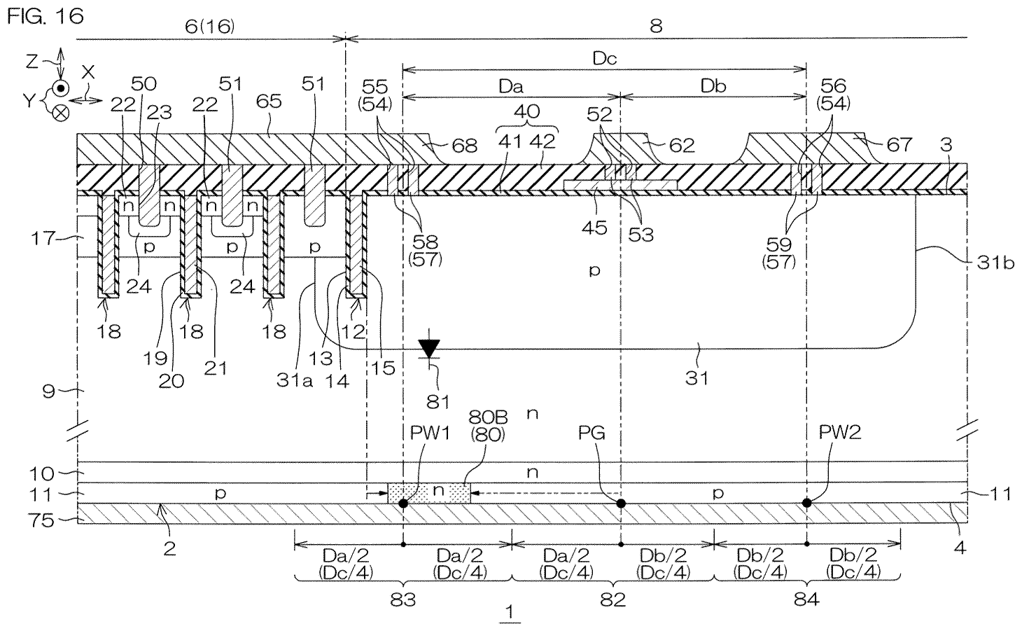

FIG. 16 is a cross-sectional view showing a cross-sectional structure of the peripheral edge portion of the chip 2 with a cathode region 80B according to a second layout example. With reference to FIG. 16, the semiconductor device 1 may include the cathode region 80B according to the second layout example as the cathode region 80. The cathode region 80B is formed at an interval along the second main surface 4 from the gate reference position PG. Specifically, the cathode region 80B is arranged at an interval along the second main surface 4 from the gate reference position PG toward the first well reference position PW1.

The cathode region 80B is arranged within the first permitted range 83 but not within the prohibited range 82. In this embodiment, the prohibited range 82 and the second permitted range 84 according to the first or second setting example may be applied. The cathode region 80B is arranged at the first well reference position PW1 and opposes the plurality of first well connection electrodes 58 in the thickness direction of the chip 2. The cathode region 80B is arranged at an interval from the gate line electrode 62 toward the first well reference position PW1 so as not to oppose the gate line electrode 62 in the thickness direction of the chip 2.

The cathode region 80B is arranged at an interval from a position immediately below the center of the gate line wiring 45 toward the first well reference position PW1. The cathode region 80B is arranged at intervals from positions immediately below the plurality of gate connection electrodes 53 toward the first well reference position PW1 so as not to oppose the plurality of gate connection electrodes 53 in the thickness direction of the chip 2. The cathode region 80B is arranged at an interval from the gate line wiring 45 toward the first well reference position PW1 so as not to oppose the gate line wiring 45 in the thickness direction of the chip 2.

The cathode region 80B is preferably formed at an interval from a position immediately below the inner edge 31a of the well region 31 toward the first well reference position PW1 regardless of the first permitted range 83. That is, the cathode region 80B is formed only in a region that opposes the well region 31 in the thickness direction of the chip 2 in the surface layer portion of the second main surface 4.

Also, the cathode region 80B is preferably formed at intervals from the plurality of trench gate structures 18 toward the peripheral edge of the second main surface 4 so as not to oppose the plurality of trench gate structures 18 in the thickness direction of the chip 2. It is particularly preferable that the cathode region 80B is formed at an interval from the trench isolation structure 12 toward the peripheral edge of the second main surface 4 so as not to oppose the trench isolation structure 12 in the thickness direction of the chip 2.

That is, the cathode region 80B is preferably formed at an interval from the IGBT region 6 toward the peripheral edge of the chip 2 so as not to oppose the IGBT region 17 in the thickness direction of the chip 2. That is, the cathode region 80B is preferably not formed in the IGBT region 6, but only in the outer peripheral region 8. In this case, the IGBT region 6 can have reduced electrical impact on the diode 81 and, at the same time, the diode 81 can have reduced electrical impact on the IGBT region 6.

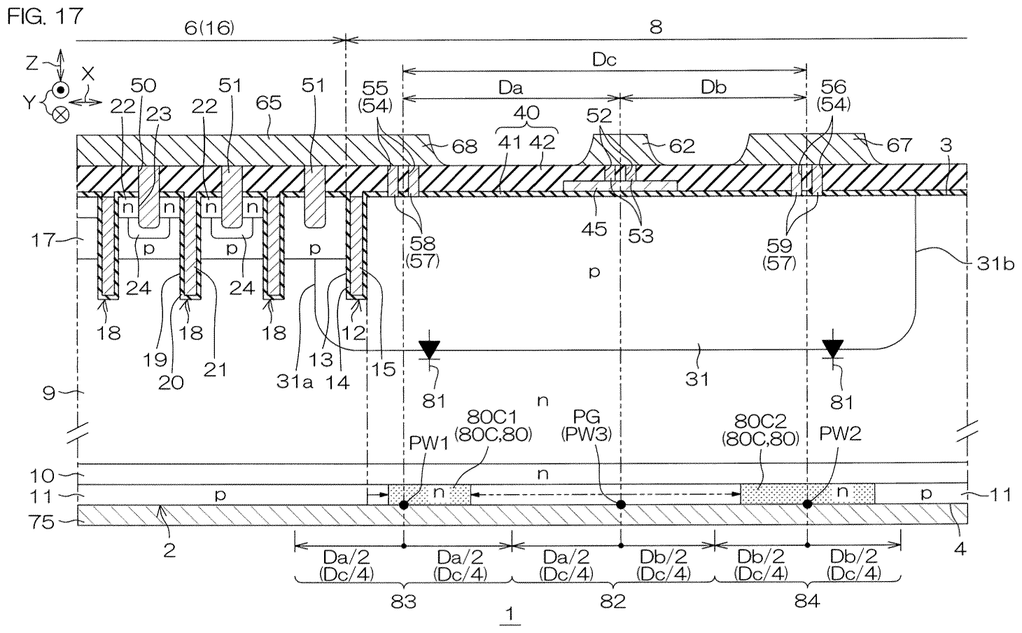

FIG. 17 is a cross-sectional view showing a cross-sectional structure of the peripheral edge portion of the chip 2 with a cathode region 80C according to a third layout example. With reference to FIG. 17, the semiconductor device 1 may include the cathode region 80C according to the third layout example as the cathode region 80. The cathode region 80C includes a first cathode region 80C1 that is arranged nearer the first well reference position PW1 and a second cathode region 80C2 that is arranged nearer the second well reference position PW2 at an interval from the first cathode region 80C1.

The first cathode region 80C1 is formed in a layout similar to the cathode region 80 according to the second layout example (see FIG. 16). The second cathode region 80C2 is formed in a layout similar to the cathode region 80 according to the first layout example (see FIG. 5). The second cathode region 80C2 opposes the first cathode region 80C1 with a portion of the collector region 11 therebetween in the surface layer portion of the second main surface 4.

The portion of the collector region 11 opposes the gate line wiring 45, the gate connection electrodes 53, and the gate line electrode 62 in the thickness direction of the chip 2. The portion of the collector region 11 preferably opposes the entire gate line electrode 62 in the thickness direction of the chip 2. The portion of the collector region 11 preferably opposes the entire gate line wiring 45 in the thickness direction of the chip 2.

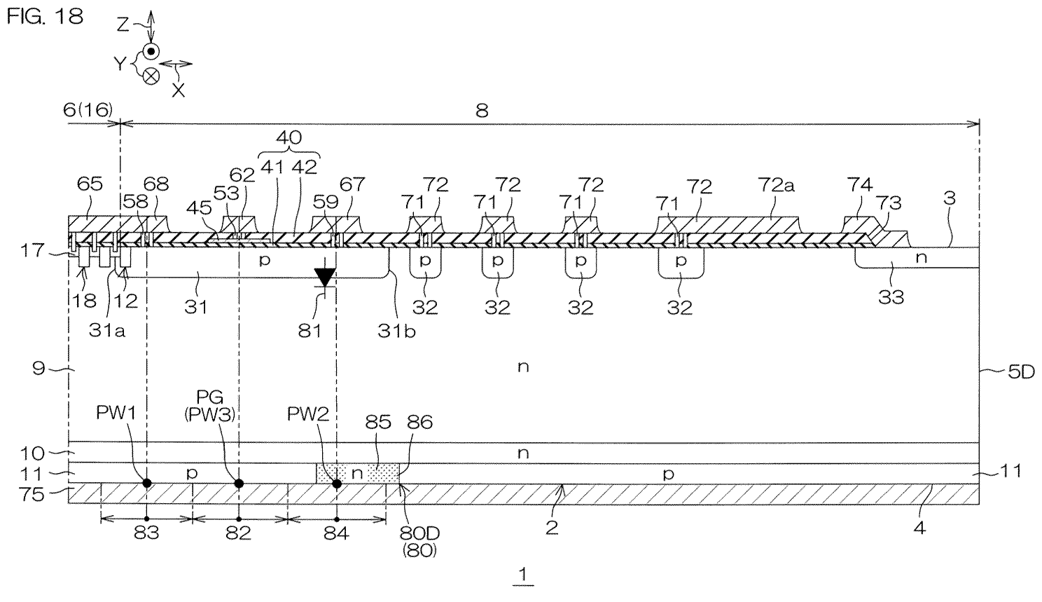

FIG. 18 is a cross-sectional view showing a cross-sectional structure of the peripheral edge portion of the chip 2 with a cathode region 80D according to a fourth layout example. With reference to FIG. 18, the semiconductor device 1 may include the cathode region 80D according to the fourth layout example as the cathode region 80. The cathode region 80D has an opposing portion 85 that opposes the well region 31 in the thickness direction of the chip 2 and a cathode drawer portion 86 that is drawn out from the opposing portion 85 toward the peripheral edge of the chip 2.

The opposing portion 85 is arranged at an interval along the second main surface 4 from the gate reference position PG toward the second well reference position PW2. The opposing portion 85 is arranged within the second permitted range 84 but not within the prohibited range 82. In this embodiment, the prohibited range 82 and the second permitted range 84 according to the first or second setting example may be applied.

The opposing portion 85 is arranged at the second well reference position PW2 and opposes the plurality of second well connection electrodes 59 in the thickness direction of the chip 2. The opposing portion 85 is arranged at an interval from the gate line electrode 62 toward the second well reference position PW2 so as not to oppose the gate line electrode 62 in the thickness direction of the chip 2.

The opposing portion 85 is arranged at an interval from a position immediately below the center of the gate line wiring 45 toward the second well reference position PW2. The opposing portion 85 is arranged at intervals from positions immediately below the centers of the plurality of gate connection electrodes 53 toward the second well reference position PW2 so as not to oppose the plurality of gate connection electrodes 53 in the thickness direction of the chip 2. The opposing portion 85 is arranged at an interval from the gate line wiring 45 toward the second well reference position PW2 so as not to oppose the gate line wiring 45 in the thickness direction of the chip 2.

The cathode drawer portion 86 is drawn out from the opposing portion 85 across a position immediately below the outer edge 31b of the well region 31 toward the peripheral edge of the chip 2. The cathode drawer portion 86 is formed at intervals from the plurality of field regions 32 (the innermost field region 32) toward the well region 31 so as not to oppose the plurality of field regions 32 in the thickness direction of the chip 2. The cathode region 80D may have a width that is smaller or not smaller than the width of the emitter line electrode 67.

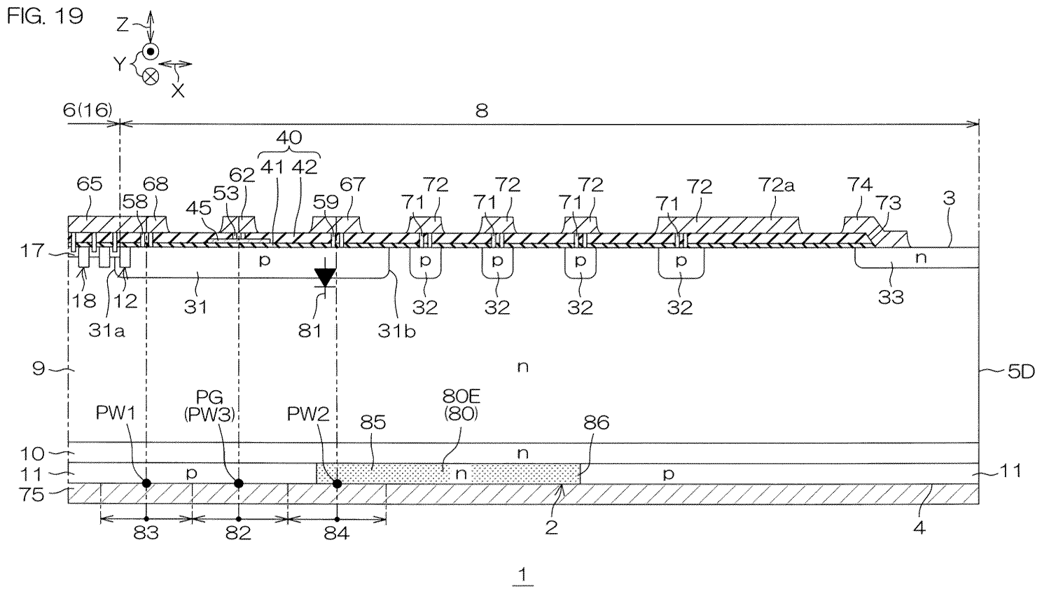

FIG. 19 is a cross-sectional view showing a cross-sectional structure of the peripheral edge portion of the chip 2 with a cathode region 80E according to a fifth layout example. With reference to FIG. 19, the semiconductor device 1 may include the cathode region 80E according to the fifth layout example as the cathode region 80. The cathode region 80E is formed by deforming the cathode region 80D according to the above-described fourth layout example.

Specifically, the cathode region 80E includes a cathode drawer portion 86 that opposes at least one of the field regions 32 (at least the innermost field region 32) in the thickness direction of the chip 2. The cathode drawer portion 86 is formed at an interval from a region immediately below the outermost field region 32 (the outermost field electrode 72) toward the well region 31 so as not to oppose the outermost field region 32 (the field electrode 72) in the thickness direction of the chip 2.

The cathode region 80E may have a width that is smaller or not smaller than the width of the emitter line electrode 67. The cathode region 80E may have a width that is smaller or not smaller than the width of the well region 31. The cathode region 80E according to the fifth layout example may be applied to the first cathode region 80C1 according to the third layout example.

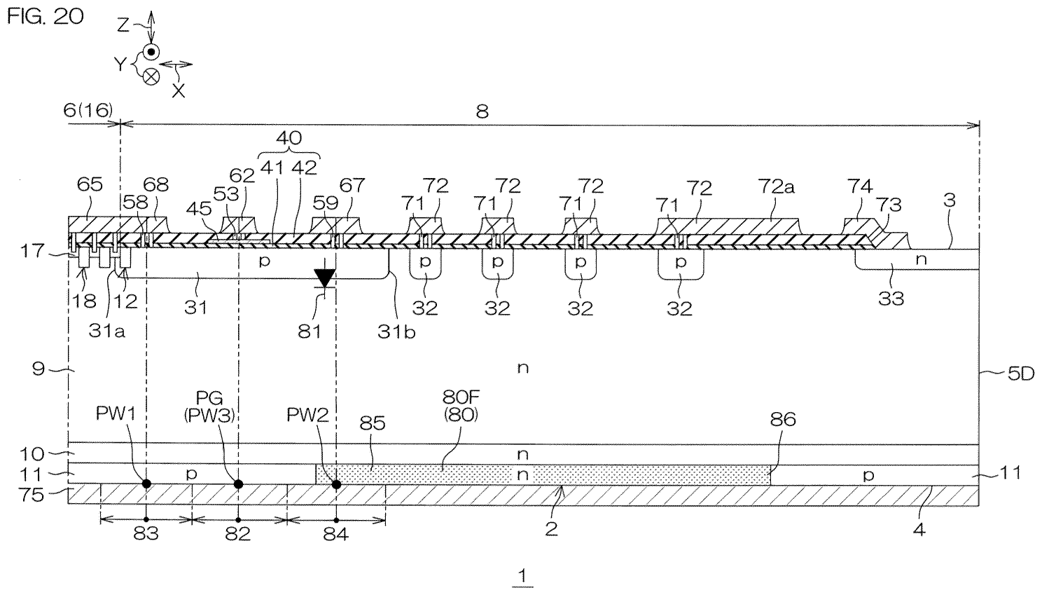

FIG. 20 is a cross-sectional view showing a cross-sectional structure of the peripheral edge portion of the chip 2 with a cathode region 80F according to a sixth layout example. With reference to FIG. 20, the semiconductor device 1 may include the cathode region 80F according to the sixth layout example as the cathode region 80. The cathode region 80F is formed by deforming the cathode region 80E according to the above-described fifth layout example.

Specifically, the cathode region 80F includes a cathode drawer portion 86 that opposes all of the field regions 32 (the field electrodes 72) in the thickness direction of the chip 2. The cathode drawer portion 86 is formed at an interval from a region immediately below the channel stop region 33 toward the well region 31 so as not to oppose the channel stop region 33 in the thickness direction of the chip 2. The cathode drawer portion 86 does not oppose the channel stop electrode 74, either.

The cathode region 80F may have a width that is not smaller than the width of the emitter line electrode 67. The cathode region 80F may have a width that is not smaller than the width of the well region 31. The cathode region 80F according to the sixth layout example may be applied to the first cathode region 80C1 according to the third layout example.

As described above, the semiconductor device 1 includes the chip 2, the IGBT region 6, the outer peripheral region 8, the p-type well region 31, the insulating film 40, the well connection electrodes 57, and the n-type cathode region 80. The chip 2 has the first main surface 3 on one side and the second main surface 4 on the other side. The IGBT region 6 is provided in an inner portion of the first main surface 3. The outer peripheral region 8 is provided in a peripheral edge portion of the chip 2. The well region 31 is formed in the surface layer portion of the first main surface 3 within the outer peripheral region 8 so as to define the IGBT region 6.

The insulating film 40 covers the well region 31. The well connection electrodes 57 are embedded in the insulating film 40 so as to be connected to the well region 31. The cathode region 80 is formed in the surface layer portion of the second main surface 4 within the outer peripheral region 8 so as to oppose the well connection electrodes 57, and forms a diode 81 with the well region 31. In accordance with the structure, a current pathway can be formed that linearly links the well connection electrodes 57 and the cathode region 80. This allows the diode 81 to have an increased forward current IF during the forward operation. It is therefore possible to provide the semiconductor device 1 which can increase the electrical characteristics.

The semiconductor device 1 preferably includes a gate line electrode 62 that is arranged on the insulating film 40 at intervals from the well connection electrodes 57 so as to oppose the well region 31. In this case, the cathode region 80 is preferably formed at an interval along the second main surface 4 from a position immediately below the center of the gate line electrode 62.

In accordance with the structure above, it is possible to suppress the current bypass pathway through a region immediately below the gate line electrode 62 in a region between the well connection electrodes 57 and the cathode region 80. Thus, the cathode region 80 does not preferably oppose the gate line electrode 62. In accordance with the structure, it is possible to adequately suppress the current bypass pathway through a region immediately below the gate line electrode 62.

The well connection electrodes 57 may include one or both of the first well connection electrodes 58 that are arranged nearer the inner edge 31a of the well region 31 and the second well connection electrodes 59 that are arranged nearer the outer edge 31b of the well region 31.

In a case in which the well connection electrodes 57 include the first well connection electrodes 58, the gate line electrode 62 is arranged at intervals from the first well connection electrodes 58 toward the outer edge 31b of the well region 31 (toward the peripheral edge of the chip 2). In this case, the cathode region 80 is formed at an interval along the second main surface 4 from a position immediately below the center of the gate line electrode 62 toward the inner edge 31a of the well region 31 (toward the IGBT region 6). In accordance with the structure, a current pathway can be formed that linearly links the first well connection electrodes 58 and the cathode region 80.

In this case, the semiconductor device 1 preferably includes an emitter pad electrode 66. The emitter pad electrode 66 is arranged on the insulating film 40 at an interval from the gate line electrode 62 toward the IGBT region 6 so as to be electrically connected to the well region 31 via the first well connection electrodes 58. Also, the cathode region 80 opposes the emitter pad electrode 66 in the thickness direction of the chip 2. In accordance with the structure, a current pathway can be formed that linearly links the emitter pad electrode 66 and the cathode region 80.

In a case in which the well connection electrodes 57 include the second well connection electrodes 59, the gate line electrode 62 may be arranged at intervals from the second well connection electrodes 59 toward the inner edge 31a of the well region 31 (toward the IGBT region 6). In this case, the cathode region 80 may be formed at an interval along the second main surface 4 from a position immediately below the center of the gate line electrode 62 toward the outer edge 31b of the well region 31 (toward the peripheral edge of the chip 2). In accordance with the structure, a current pathway can be formed that linearly links the second well connection electrodes 59 and the cathode region 80.

In this case, the semiconductor device 1 preferably includes the emitter line electrode 67. The emitter line electrode 67 is arranged on the insulating film 40 at an interval from the gate line electrode 62 toward the peripheral edge of the chip 2 so as to be electrically connected to the well region 31 via the second well connection electrodes 59. Additionally, the cathode region 80 opposes the emitter line electrode 67. Based on this structure, a current pathway can be formed that linearly links the emitter line electrode 67 to the cathode region 80. The emitter line electrode 67 may be arranged only in a region that opposes the well region 31.

The semiconductor device 1 may include the gate line wiring 45 and the gate connection electrodes 53. The gate line wiring 45 is arranged within the insulating film 40 so as to oppose the well region 31. The gate connection electrodes 53 are embedded in the insulating film 40 so as to be connected to the gate line wiring 45. In this case, the gate line electrode 62 is electrically connected to the gate line wiring 45 via the gate connection electrodes 53.

In the structure above, the cathode region 80 is preferably formed at an interval along the second main surface 4 from a position immediately below the center of the gate line wiring 45. In accordance with the structure, it is possible to suppress the current bypass pathway through a region immediately below the gate line wiring 45. In this case, the cathode region 80 does not preferably oppose the gate connection electrodes 53. Further, the cathode region 80 does not preferably oppose the gate line wiring 45. In accordance with the structures, it is possible to adequately suppress the current bypass pathway through a region immediately below the gate line wiring 45. The gate line electrode 62 may be formed narrower than the gate line wiring 45.

The cathode region 80 is preferably formed only in a region that opposes the well region 31 in the surface layer portion of the second main surface 4. In accordance with the structure, the current pathway of the forward current IF can be reliably limited within a region between the well region 31 and the cathode region 80. It is therefore possible to adequately inhibit reduction in the forward current IF. In accordance with the structure, the peak surge current IFSM can also be increased.

As a matter of course, the cathode region 80D may include the opposing portion 85 that opposes the well region 31 and the cathode drawer portion 86 that is drawn out from the opposing portion 85 toward the peripheral edge of the chip 2. Even in such a structure, since a current pathway is formed that linearly links the well connection electrodes 57 and the cathode region 80, the forward current IF can be inhibited from being reduced. In accordance with the structure, the peak surge current IFSM can also be increased.

The semiconductor device 1 may include the p-type field regions 32 that are formed at intervals from the well region 31 toward the peripheral edge of the chip 2 in the surface layer portion of the first main surface 3 within the outer peripheral region 8. In this case, the cathode drawer portion 86 may be formed so as not to oppose the field regions 32 or may be formed so as to oppose the field regions 32.

The semiconductor device 1 may include the n-type channel stop region 33 that is formed at intervals from the field regions 32 toward the peripheral edge of the chip 2 in the surface layer portion of the first main surface 3 within the outer peripheral region 8. In this case, the cathode drawer portion 86 is preferably formed so as not to oppose the channel stop region 33.

From another perspective, the semiconductor device 1 includes the chip 2, the IGBT region 6, the outer peripheral region 8, the well region 31, the insulating film 40, the well connection electrodes 57, the gate line electrode 62, and the cathode region 80. The chip 2 has the first main surface 3 on one side and the second main surface 4 on the other side. The IGBT region 6 is provided in an inner portion of the first main surface 3. The outer peripheral region 8 is provided in a peripheral edge portion of the chip 2. The well region 31 is formed in the surface layer portion of the first main surface 3 within the outer peripheral region 8 so as to define the IGBT region 6.

The insulating film 40 covers the well region 31. The well connection electrodes 57 are embedded in the insulating film 40 so as to be connected to the well region 31. The gate line electrode 62 is arranged on the insulating film 40 at intervals from the well connection electrodes 57 so as to oppose the well region 31.

The cathode region 80 is formed in the surface layer portion of the second main surface 4 so as to oppose the well region 31 and forms a diode 81 with the well region 31. The cathode region 80 is arranged at an interval along the second main surface 4 from the gate reference position PG immediately below the center of the gate line electrode 62 toward the well connection electrodes 57.

In accordance with the structure above, it is possible to suppress the current bypass pathway through a region immediately below the gate line electrode 62 in a region between the well connection electrodes 57 and the cathode region 80 and, at the same time, to shorten the current pathway between the well connection electrodes 57 and the cathode region 80. This allows the diode 81 to have an increased forward current IF during the forward operation. It is therefore possible to provide the semiconductor device 1 which can increase the electrical characteristics.

The well connection electrodes 57 may include one or both of the first well connection electrodes 58 that are arranged nearer the inner edge 31a of the well region 31 and the second well connection electrodes 59 that are arranged nearer the outer edge 31b of the well region 31.

In a case in which the well connection electrodes 57 include the first well connection electrodes 58, provided that the distance between the center of the gate line electrode 62 and the first well connection electrodes 58 is represented as the first reference distance Da, the cathode region 80 is preferably not arranged within a range (prohibited range 82) that does not exceed one-half of the first reference distance Da from the gate reference position PG. In accordance with the structure, it is possible to adequately suppress the current bypass pathway through a region immediately below the gate line electrode 62 and thereby to increase the forward current IF.

Provided that the distance between the center of the gate line electrode 62 and the well connection electrodes 57 is represented as the first reference distance Da, the cathode region 80 preferably has a portion that is arranged within a range (first permitted range 83) that does not exceed one-half of the first reference distance Da from the first well reference position PW1 immediately below the first well connection electrodes 58. In accordance with the structure, the forward current IF can be increased adequately.

Therefore, it is preferable that cathode region 80 is arranged within a range (first permitted range 83) that does not exceed one-half of the first reference distance Da from the first well reference position PW1 and that cathode region 80 is not arranged within a range (prohibited range 82) that does not exceed one-half of the first reference distance Da from the gate reference position PG.

In a case in which the well connection electrodes 57 include the second well connection electrodes 58, provided that the distance between the center of the gate line electrode 62 and the second well connection electrodes 59 is represented as the second reference distance Db, the cathode region 80 is preferably not arranged within a range (prohibited range 82) that does not exceed one-half of the second reference distance Db from the gate reference position PG. In accordance with the structure, it is possible to adequately suppress the current bypass pathway through a region immediately below the gate line electrode 62 and thereby to increase the forward current IF.

Provided that the distance between the center of the gate line electrode 62 and the well connection electrodes 57 is represented as the second reference distance Db, the cathode region 80 preferably has a portion that is arranged within a range (second permitted range 84) that does not exceed one-half of the second reference distance Db from the second well reference position PW2 immediately below the second well connection electrodes 59. In accordance with the structure, the forward current IF can be increased adequately.

It is therefore particularly preferable that the cathode region 80 has a portion that is arranged within a range (second permitted range 84) that does not exceed one-half of the second reference distance Db from the second well reference position PW2, and that the cathode region 80 is not arranged within a range (prohibited range 82) that does not exceed one-half of the second reference distance Db from the gate reference position PG.

From a further point of view, the semiconductor device 1 includes the chip 2, the IGBT region 6, the outer peripheral region 8, the well region 31, the insulating film 40, the first well connection electrodes 58, the second well connection electrodes 59, and the cathode region 80. The chip 2 has the first main surface 3 on one side and the second main surface 4 on the other side. The IGBT region 6 is provided in an inner portion of the first main surface 3. The outer peripheral region 8 is provided in a peripheral edge portion of the chip 2. The well region 31 is formed in the surface layer portion of the first main surface 3 within the outer peripheral region 8 so as to define the IGBT region 6. The insulating film 40 covers the well region 31.

The first well connection electrodes 58 are embedded in the insulating film 40 so as to be connected to the well region 31. The second well connection electrodes 59 are embedded in the insulating film 40 at intervals from the first well connection electrodes 58 toward the peripheral edge of the chip 2 so as to be connected to the well region 31. The cathode region 80 is formed in the surface layer portion of the second main surface 4 so as to oppose the well region 31, and forms a diode 81 with the well region 31. The cathode region 80 is formed at an interval along the second main surface 4 from the intermediate reference position PW3 immediately below the middle between the first well connection electrodes 58 and the second well connection electrodes 59.

In accordance with the structure above, the current bypass pathway can be suppressed through a region immediately below the middle between the first well connection electrodes 58 and the second well connection electrodes 59. This allows the diode 81 to have an increased forward current IF during the forward operation. It is therefore possible to provide the semiconductor device 1 which can increase the electrical characteristics.

In this case, provided that the distance between the first well connection electrodes 58 and the second well connection electrodes 59 is represented as the third reference distance Dc, the cathode region 80 is preferably not arranged within a range (prohibited range 82) that does not exceed one-fourth of the third reference distance Dc from the intermediate reference position PW3. In accordance with the structure above, the current bypass pathway can be suppressed adequately through a region immediately below the middle between the first well connection electrodes 58 and the second well connection electrodes 59.

The cathode region 80 may be arranged at an interval from the intermediate reference position PW3 toward the first well connection electrodes 58. In accordance with the structure, it is possible to shorten the current pathway between the first well connection electrodes 58 and the cathode region 80 and thereby to increase the forward current IF.

In this case, provided that the distance between the first well connection electrodes 58 and the second well connection electrodes 59 is represented as the third reference distance Dc, the cathode region 80 preferably has a portion that is arranged within a range (first permitted range 83) that does not exceed one-fourth of the third reference distance Dc from the first well reference position PW1 immediately below the first well connection electrodes 58.

In accordance with the structure, it is possible to shorten the current pathway between the first well connection electrodes 58 and the cathode region 80 and thereby to increase the forward current IF adequately. The cathode region 80 thus preferably has a portion that overlaps the first well reference position PW1. In accordance with the structure, it is possible to form a current pathway that linearly links the first well connection electrodes 58 and the cathode region 80 and thereby to increase the forward current IF adequately.

The cathode region 80 may be arranged at an interval from the intermediate reference position PW3 toward the second well connection electrodes 59. In accordance with the structure, it is possible to shorten the current pathway between the second well connection electrodes 59 and the cathode region 80 and thereby to increase the forward current IF.

In this case, provided that the distance between the first well connection electrodes 58 and the second well connection electrodes 59 is represented as the third reference distance Dc, the cathode region 80 preferably has a portion that is arranged within a range (second permitted range 84) that does not exceed one-fourth of the third reference distance Dc from the second well reference position PW2 immediately below the second well connection electrodes 59.

In accordance with the structure, it is possible to shorten the current pathway between the second well connection electrodes 59 and the cathode region 80 and thereby to increase the forward current IF adequately. The cathode region 80 thus preferably has a portion that overlaps the second well reference position PW2. In accordance with the structure, it is possible to form a current pathway that linearly links the second well connection electrodes 59 and the cathode region 80 and thereby to increase the forward current IF adequately.

The above-described embodiments may be implemented in other forms. The above-described embodiments illustrate an example in which the plurality of emitter connection electrodes 51 are separate from the emitter pad electrode 66 (the emitter electrode 65). However, a portion of the emitter pad electrode 66 may be utilized to form the plurality of emitter connection electrodes 51. That is, the emitter pad electrode 66 may be arranged on the insulating film 40 so as to enter the plurality of emitter openings 50. In this case, a plurality of portions of the emitter pad electrode 66 that are positioned within the plurality of emitter openings 50 are formed as the plurality of emitter connection electrodes 51.

The above-described embodiments illustrate an example in which the plurality of gate connection electrodes 53 are separate from the gate electrode 60 (the gate line electrode 62). However, a portion of the gate electrode 60 may be utilized to form the plurality of gate connection electrodes 53. That is, the gate electrode 60 may be arranged on the insulating film 40 so as to enter the plurality of gate openings 52. In this case, a plurality of portions of the gate electrode 60 that are positioned within the plurality of gate openings 52 are formed as the plurality of gate connection electrodes 53.

The above-described embodiments illustrate an example in which the plurality of first well connection electrodes 58 are separate from the emitter pad electrode 66 (the emitter electrode 65). However, a portion of the emitter pad electrode 66 may be utilized to form the plurality of first well connection electrodes 58. That is, the emitter pad electrode 66 may be arranged on the insulating film 40 so as to enter the plurality of first well openings 55. In this case, a plurality of portions of the emitter pad electrode 66 that are positioned within the plurality of first well openings 55 are formed as the plurality of first well connection electrodes 58.

The above-described embodiments illustrate an example in which the plurality of second well connection electrodes 59 are separate from the emitter line electrode 67 (the emitter electrode 65). However, a portion of the emitter line electrode 67 may be utilized to form the plurality of second well connection electrodes 59. That is, the emitter line electrode 67 may be arranged on the insulating film 40 so as to enter the plurality of second well openings 56. In this case, a plurality of portions of the emitter line electrode 67 that are positioned within the plurality of second well openings 56 are formed as the plurality of second well connection electrodes 59.

The above-described embodiments illustrate an example in which the plurality of field connection electrodes 71 are separate from the field electrodes 72. However, portions of each field electrode 72 may be utilized to form the plurality of field connection electrodes 71. That is, each field electrode 72 may be arranged on the insulating film 40 so as to enter the plurality of field openings 70. In this case, a plurality of portions of each field electrode 72 that are positioned within the plurality of field openings 70 are formed as the plurality of field connection electrodes 71.

The above-described embodiments each illustrate an example in which the chip 2 consists of a silicon single crystal substrate. However, the chip 2 may consist of a wide bandgap semiconductor single crystal substrate. For example, the chip 2 may consist of an SiC (silicon carbide) single crystal substrate or a GaN single crystal substrate and the like.

In the above-described embodiments, the n-type semiconductor region may be replaced with the p-type semiconductor region, and the p-type semiconductor region may be replaced with the n-type semiconductor region. A specific configuration in this case is obtained by replacing “n-type” with “p-type” and simultaneously replacing “p-type” with “n-type” in the foregoing description and the accompanying drawings.

In the above-described embodiments, the first direction X and the second direction Y are defined by the directions in which the first to fourth side surfaces 5A to 5D extend. However, the first direction X and the second direction Y may be any direction as long as they maintain a mutually intersecting (specifically, orthogonal) relationship. For example, the first direction X may be a direction intersecting the first to fourth side surfaces 5A to 5D, and the second direction Y may be a direction intersecting the first to fourth side surfaces 5A to 5D.

Example features extracted from the description and the accompanying drawings will be set forth below. Alphanumeric characters and the like in parentheses will hereinafter represent corresponding components and the like in the above-described embodiments, though not intended to limit the scope of each clause to the embodiments. “Semiconductor device” according to the following clauses may be replaced with “semiconductor switching device” or “RC-IGBT semiconductor device.”

[A1] A semiconductor device (1) comprising: a chip (2) that has a first main surface (3) on one side and a second main surface (4) on the other side; an IGBT region (6) that is provided in an inner portion of the first main surface (3); an outer peripheral region (8) that is provided in a peripheral edge portion of the first main surface (3); a first conductivity type (p-type) well region (31) that is formed in a surface layer portion of the first main surface (3) in the outer peripheral region (8) so as to define the IGBT region (6); an insulating film (40) that covers the well region (31); a well connection electrode (57, 58, 59) that is embedded in the insulating film (40) so as to be connected to the well region (31); and a second conductivity type (n-type) cathode region (80, 80A to 80F) that is formed in a surface layer portion of the second main surface (4) in the outer peripheral region (8) so as to oppose the well connection electrode (57, 58, 59), and that forms a diode (81) with the well region (31).

[A2] The semiconductor device (1) according to A1, further including: a gate electrode (62) that is arranged on the insulating film (40) at an interval from the well connection electrode (57, 58, 59) so as to oppose the well region (31).

[A3] The semiconductor device (1) according to A2, wherein the cathode region (80, 80A to 80F) is formed at an interval along the second main surface (4) from a position immediately below a center of the gate electrode (62).

[A4] The semiconductor device (1) according to A2 or A3, wherein the gate electrode (62) is arranged at an interval from the well connection electrode (57, 58, 59) toward the IGBT region (6).

[A5] The semiconductor device (1) according to A4, wherein the cathode region (80, 80A to 80F) is formed at an interval along the second main surface (4) from a position immediately below a center of the gate electrode (62) toward a peripheral edge of the chip (2).

[A6] The semiconductor device (1) according to A4 or A5, further including: an emitter electrode (67) that is arranged on the insulating film (40) at an interval from the gate electrode (62) toward a peripheral edge of the chip (2), and that is electrically connected to the well region (31) via the well connection electrode (57, 58, 59); and wherein the cathode region (80, 80A to 80F) opposes the emitter electrode (67).

[A7] The semiconductor device (1) according to A6, wherein the emitter electrode (67) is arranged only in a region that opposes the well region (31) in a cross-sectional view.

[A8] The semiconductor device (1) according to A2 or A3, wherein the gate electrode (62) is arranged at an interval from the well connection electrode (57, 58, 59) toward a peripheral edge of the chip (2).

[A9] The semiconductor device (1) according to A8, wherein the cathode region (80, 80A to 80F) is formed at an interval along the second main surface (4) from a position immediately below a center of the gate electrode (62) toward the IGBT region (6).

[A10] The semiconductor device (1) according to A8 or A9, further comprising: an emitter pad electrode (66) that is arranged on the insulating film (40) at an interval from the gate electrode (62) toward the IGBT region (6) so as to be electrically connected to the well region (31) via the well connection electrode (57, 58, 59); and wherein the cathode region (80, 80A to 80F) opposes the emitter pad electrode (66).

[A11] The semiconductor device (1) according to any one of A2 to A10, wherein the cathode region (80, 80A to 80F) does not oppose the gate electrode (62).

[A12] The semiconductor device (1) according to any one of A2 to A11, further comprising: a gate wiring (45) that is arranged within the insulating film (40) so as to oppose the well region (31), and a gate connection electrode (53) that is embedded in the insulating film (40) so as to be connected to the gate wiring (45); and wherein the gate electrode (62) is electrically connected to the gate wiring (45) via the gate connection electrode (53).

[A13] The semiconductor device (1) according to A12, wherein the cathode region (80, 80A to 80F) is formed at an interval along the second main surface (4) from a position immediately below a center of the gate wiring (45).

[A14] The semiconductor device (1) according to A12 or A13, wherein the cathode region (80, 80A to 80F) does not oppose the gate connection electrode (53).

[A15] The semiconductor device (1) according to any one of A12 to A14, wherein the cathode region (80, 80A to 80F) does not oppose the gate wiring (45).

[A16] The semiconductor device (1) according to any one of A12 to A15, wherein the gate electrode (62) is formed narrower than the gate wiring (45).

[A17] The semiconductor device (1) according to any one of A1 to A16, wherein the cathode region (80, 80A to 80F) is formed only in a region that opposes the well region (31) in a surface layer portion of the second main surface (4).

[A18] The semiconductor device (1) according to any one of A1 to A16, wherein the cathode region (80, 80A to 80F) includes an opposing portion (85) that opposes the well region (31) and a drawer portion (86) that is drawn out from the opposing portion (85) toward a peripheral edge of the chip (2).

[A19] The semiconductor device (1) according to A18, further comprising: a first conductivity type (p-type) field region (32) that is formed in the surface layer portion of the first main surface (3) at an interval from the well region (31) toward a peripheral edge of the chip (2) within the outer peripheral region (8); and wherein the drawer portion (86) does not oppose the field region (32).

[A20] The semiconductor device (1) according to A18, further comprising: a first conductivity type (p-type) field region (32) that is formed in the surface layer portion of the first main surface (3) at an interval from the well region (31) toward a peripheral edge of the chip (2) within the outer peripheral region (8); and wherein the drawer portion (86) opposes the field region (32).

[A21] The semiconductor device (1) according to any one of A1 to A20, further comprising: a first conductivity type (p-type) base region (17) that is formed in the surface layer portion of the first main surface (3) within the IGBT region (6).

[A22] The semiconductor device (1) according to A21, wherein the cathode region does not oppose the base region (17).

[A23] The semiconductor device (1) according to A21 or A22, wherein the well region (31) is deeper than the base region (17).

[A24] The semiconductor device (1) according to any one of A21 to A23, wherein the well region (31) is drawn out from the outer peripheral region (8) to the IGBT region (6) and has a portion that is connected to the base region (17).

[A25] The semiconductor device (1) according to any one of A1 to A24, further comprising: a trench gate structure (18) that is formed in the first main surface (3) within the IGBT region (6).

[A26] The semiconductor device (1) according to A25, wherein the cathode region does not oppose the trench gate structure (18).

[A27] The semiconductor device (1) according to A25 or A26, wherein the well region (31) is drawn out from the outer peripheral region (8) to the IGBT region (6) and has a portion that covers the bottom wall of the trench gate structure (18).

[B1] A semiconductor device (1) comprising: a chip (2) that has a first main surface (3) on one side and a second main surface (4) on the other side; an IGBT region (6) that is provided in an inner portion of the first main surface (3); an outer peripheral region (8) that is provided in a peripheral edge portion of the first main surface (3); a first conductivity type (p-type) well region (31) that is formed in a surface layer portion of the first main surface (3) in the outer peripheral region (8) so as to define the IGBT region (6); an insulating film (40) that covers the well region (31); a well connection electrode (57, 58, 59) that is embedded in the insulating film (40) so as to be connected to the well region (31); a gate electrode (62) that is arranged on the insulating film (40) at an interval from the well connection electrode (57, 58, 59) so as to oppose the well region (31); and a second conductivity type (n-type) cathode region (80, 80A to 80F) that is formed in a surface layer portion of the second main surface (4) at an interval along the second main surface (4) from a gate reference position (PG) immediately below a center of the gate electrode (62) toward the well connection electrode (57, 58, 59) so as to oppose the well region (31), and that forms a diode (81) with the well region (31).

[B2] The semiconductor device (1) according to B1, wherein provided that a distance between the center of the gate electrode (62) and the well connection electrode (57, 58, 59) is represented as a reference distance (Da, Db), the cathode region (80, 80A to 80F) is not arranged within a range (82) that does not exceed one-half of the reference distance (Da, Db) from the gate reference position (PG) toward the well connection electrode (57, 58, 59).

[B3] The semiconductor device (1) according to B1, wherein provided that a distance between the center of the gate electrode (62) and the well connection electrode (57, 58, 59) is represented as a reference distance (Da, Db), the cathode region (80, 80A to 80F) has a portion that is arranged within a range (83, 84) that does not exceed one-half of the reference distance (Da, Db) from a well reference position (PW1, PW2) immediately below the well connection electrode (57, 58, 59).

[B4] The semiconductor device (1) according to B3, wherein the cathode region (80, 80A to 80F) is not arranged within a range (82) that does not exceed one-half of the reference distance (Da, Db) from the gate reference position (PG) toward the well connection electrode (57, 58, 59).

[B5] The semiconductor device (1) according to any one of B1 to B4, wherein the cathode region (80, 80A to 80F) has a portion that opposes the well connection electrode (57, 58, 59).

[B6] The semiconductor device (1) according to any one of B1 to B5, wherein the cathode region (80, 80A to 80F) does not oppose the gate electrode (62).

[B7] The semiconductor device (1) according to any one of B1 to B6, wherein the gate electrode (62) is arranged at an interval from the well connection electrode (57, 58, 59) toward the IGBT region (6), and the cathode region (80, 80A to 80F) is arranged at an interval along the second main surface (4) from the gate reference position (PG) toward the well connection electrode (57, 58, 59).

[B8] The semiconductor device (1) according to B7, wherein the cathode region (80, 80A to 80F) is formed only in a region that opposes the well region (31) in the surface layer portion of the second main surface (4).

[B9] The semiconductor device (1) according to B7, wherein the cathode region (80, 80A to 80F) includes an opposing portion (85) that opposes the well region (31) and a drawer portion (86) that is drawn out from the opposing portion (85) toward a peripheral edge of the chip (2).

[B10] The semiconductor device (1) according to B9, further comprising: a first conductivity type (p-type) field region (32) that is formed in the surface layer portion of the first main surface (3) at an interval from the well region (31) toward the peripheral edge of the chip (2) within the outer peripheral region (8); and wherein the drawer portion (86) does not oppose the field region (32).

[B11] The semiconductor device (1) according to B9, further comprising: a first conductivity type (p-type) field region (32) that is formed in the surface layer portion of the first main surface (3) at an interval from the well region (31) toward the peripheral edge of the chip (2) within the outer peripheral region (8); and wherein the drawer portion (86) opposes the field region (32).

[B12] The semiconductor device (1) according to B11, further comprising: a second conductivity type (n-type) channel stop region (33) that is formed in the surface layer portion of the first main surface (3) at an interval from the field region (32) toward the peripheral edge of the chip (2) within the outer peripheral region (8); and wherein the drawer portion (86) does not oppose the channel stop region (33).

[B13] The semiconductor device (1) according to any one of B7 to B12, further comprising: an emitter electrode (67) that is arranged on the insulating film (40) so as to be electrically connected to the well region (31) via the well connection electrode (57, 58, 59).

[B14] The semiconductor device (1) according to any one of B1 to B6, wherein the gate electrode (62) is arranged at an interval from the well connection electrode (57, 58, 59) toward a peripheral edge of the chip (2), and the cathode region (80, 80A to 80F) is arranged at an interval along the second main surface (4) from the gate reference position (PG) toward the IGBT region (6).

[B15] The semiconductor device (1) according to B14, wherein the cathode region (80, 80A to 80F) is formed only in a region that opposes the well region (31) in the surface layer portion of the second main surface (4).

[B16] The semiconductor device (1) according to B14 or B15, further comprising: an emitter pad electrode (66) that is arranged on the insulating film (40) so as to be electrically connected to the well region (31) via the well connection electrode (57, 58, 59).

[B17] The semiconductor device (1) according to any one of B1 to B16, further comprising: a gate wiring (45) that is arranged within the insulating film (40) so as to oppose the well region (31); and a gate connection electrode (53) that is embedded in the insulating film (40) so as to be connected to the gate wiring (45); and wherein the gate electrode (62) is electrically connected to the gate wiring (45) via the gate connection electrode (53).

[B18] The semiconductor device (1) according to B17, wherein the cathode region (80, 80A to 80F) does not oppose the gate connection electrode (53).

[B19] The semiconductor device (1) according to B17 or B18, wherein the cathode region (80, 80A to 80F) does not oppose the gate wiring (45).

[B20] The semiconductor device (1) according to any one of B1 to B19, further comprising: a first conductivity type (p-type) collector region (11) that is formed in the surface layer portion of the second main surface (4); and wherein the cathode region (80) has a second conductivity type impurity concentration that is higher than the first conductivity type impurity concentration of the collector region (11).

[B21] The semiconductor device (1) according to any one of B1 to B20, further comprising: a first conductivity type (p-type) base region (17) that is formed in the surface layer portion of the first main surface (3) within the IGBT region (6).

[B22] The semiconductor device (1) according to B21, wherein the cathode region does not oppose the base region (17).

[B23] The semiconductor device (1) according to B21 or B22, wherein the well region (31) is deeper than the base region (17).

[B24] The semiconductor device (1) according to any one of B21 to B23, wherein the well region (31) is drawn out from the outer peripheral region (8) to the IGBT region (6) and has a portion that is connected to the base region (17).

[B25] The semiconductor device (1) according to any one of B1 to B24, further comprising: a trench gate structure (18) that is formed in the first main surface (3) within the IGBT region (6).

[B26] The semiconductor device (1) according to B25, wherein the cathode region does not oppose the trench gate structure (18).

[B27] The semiconductor device (1) according to B25 or B26, wherein the well region (31) is drawn out from the outer peripheral region (8) to the IGBT region (6) and has a portion that covers the bottom wall of the trench gate structure (18).

[C1] A semiconductor device (1) comprising: a chip (2) that has a first main surface (3) on one side and a second main surface (4) on the other side; an IGBT region (6) that is provided in an inner portion of the first main surface (3); an outer peripheral region (8) that is provided in a peripheral edge portion of the first main surface (3); a first conductivity type (p-type) well region (31) that is formed in a surface layer portion of the first main surface (3) in the outer peripheral region (8) so as to define the IGBT region (6); an insulating film (40) that covers the well region (31); a first well connection electrode (58) that is embedded in the insulating film (40) so as to be connected to the well region (31); a second well connection electrode (59) that is embedded in the insulating film (40) at an interval from the first well connection electrode (58) toward a peripheral edge of the chip (2) so as to be connected to the well region (31); and a second conductivity type (n-type) cathode region (80, 80A to 80F) that is formed in a surface layer portion of the second main surface (4) at an interval along the second main surface (4) from an intermediate reference position (PW3) immediately below the middle between the first well connection electrode (58) and the second well connection electrode (59) so as to oppose the well region (31), and that forms a diode (81) with the well region (31).

[C2] The semiconductor device (1) according to C1, wherein provided that a distance between the first well connection electrode (58) and the second well connection electrode (59) is represented as a reference distance (Dc), the cathode region (80, 80A to 80F) is not arranged within a range (82) that does not exceed one-fourth of the reference distance (Dc) from the intermediate reference position (PW3).

[C3] The semiconductor device (1) according to C1, wherein the cathode region (80, 80A to 80F) is arranged at an interval from the intermediate reference position (PW3) toward the first well connection electrode (58).

[C4] The semiconductor device (1) according to C3, wherein provided that a distance between the first well connection electrode (58) and the second well connection electrode (59) is represented as a reference distance (Dc), the cathode region (80, 80A to 80F) is not arranged within a range (82) that does not exceed one-fourth of the reference distance (Dc) from the intermediate reference position (PW3) toward the first well connection electrode (58).

[C5] The semiconductor device (1) according to C3, wherein provided that a distance between the first well connection electrode (58) and the second well connection electrode (59) is represented as a reference distance (Dc), the cathode region (80, 80A to 80F) has a portion that is arranged within a range (83) that does not exceed one-fourth of the reference distance (Dc) from a first well reference position (PW1) immediately below the first well connection electrode (58) toward the intermediate reference position (PW3).

[C6] The semiconductor device (1) according to C5, wherein the cathode region (80, 80A to 80F) is not arranged within a range (82) that does not exceed one-fourth of the reference distance (Dc) from the intermediate reference position (PW3) toward the first well connection electrode (58).

[C7] The semiconductor device (1) according to any one of C3 to C6, wherein the cathode region (80, 80A to 80F) opposes the first well connection electrode (58).

[C8] The semiconductor device (1) according to C1, wherein the cathode region (80, 80A to 80F) is arranged at an interval from the intermediate reference position (PW3) toward the second well connection electrode (59).

[C9] The semiconductor device (1) according to C8, wherein provided that a distance between the first well connection electrode (58) and the second well connection electrode (59) is represented as a reference distance (Dc), the cathode region (80, 80A to 80F) is not arranged within a range (82) that does not exceed one-fourth of the reference distance (Dc) from the intermediate reference position (PW3) toward the second well connection electrode (59).

[C10] The semiconductor device (1) according to C8, wherein provided that a distance between the first well connection electrode (58) and the second well connection electrode (59) is represented as a reference distance (Dc), the cathode region (80, 80A to 80F) has a portion that is arranged within a range (84) that does not exceed one-fourth of the reference distance (Dc) from a second well reference position (PW2) immediately below the second well connection electrode (59) toward the intermediate reference position (PW3).

[C11] The semiconductor device (1) according to C10, wherein the cathode region (80, 80A to 80F) is not arranged within a range (82) that does not exceed one-fourth of the reference distance (Dc) from the intermediate reference position (PW3) toward the second well connection electrode (59).

[C12] The semiconductor device (1) according to any one of C8 to A11, wherein the cathode region (80, 80A to 80F) opposes the second well connection electrode (59).

[C13] The semiconductor device (1) according to C1, wherein the cathode region (80, 80A to 80F) includes a first cathode region (80C1) that is formed at an interval from the intermediate reference position (PW3) toward the first well connection electrode (58) and a second cathode region (80C2) that is formed at an interval from the intermediate reference position (PW3) toward the second well connection electrode (59).

[C14] The semiconductor device (1) according to C13, wherein provided that a distance between the first well connection electrode (58) and the second well connection electrode (59) is represented as a reference distance (Dc), the first cathode region (801C) is not arranged within a range (82) that does not exceed one-fourth of the reference distance (Dc) from the intermediate reference position (PW3) toward the first well connection electrode (58).

[C15] The semiconductor device (1) according to C13, wherein provided that a distance between the first well connection electrode (58) and the second well connection electrode (59) is represented as a reference distance (Dc), the first cathode region (801C) has a portion that is arranged within a range (83) that does not exceed one-fourth of the reference distance (Dc) from a first well reference position (PW1) immediately below the first well connection electrode (58) toward the intermediate reference position (PW3).

[C16] The semiconductor device (1) according to C15, wherein the first cathode region (801C) is not arranged within a range (82) that does not exceed one-fourth of the reference distance (Dc) from the intermediate reference position (PW3) toward the first well connection electrode (58).

[C17] The semiconductor device (1) according to C16, wherein provided that a distance between the first well connection electrode (58) and the second well connection electrode (59) is represented as a reference distance (Dc), the second cathode region (80C2) is not arranged within a range (82) that does not exceed one-fourth of the reference distance (Dc) from the intermediate reference position (PW3) toward the second well connection electrode (59).

[C18] The semiconductor device (1) according to C16, wherein provided that a distance between the first well connection electrode (58) and the second well connection electrode (59) is represented as a reference distance (Dc), the second cathode region (80C2) has a portion that is arranged within a range (84) that does not exceed one-fourth of the reference distance (Dc) from a second well reference position (PW2) immediately below the second well connection electrode (59) toward the intermediate reference position (PW3).

[C19] The semiconductor device (1) according to C18, wherein the second well connection electrode (59) is not arranged within a range (82) that does not exceed one-fourth of the reference distance (Dc) from the intermediate reference position (PW3) toward the second well connection electrode (59).

[C20] The semiconductor device (1) according to any one of C1 to C19, further comprising: an emitter pad electrode (66) that is arranged on the insulating film (40) so as to be electrically connected to the well region (31) via the first well connection electrode (58).

[C21] The semiconductor device (1) according to any one of C1 to C20, further comprising: an emitter electrode (67) that is arranged on the insulating film (40) so as to be electrically connected to the well region (31) via the second well connection electrode (59).

[C22] The semiconductor device (1) according to any one of C1 to C21, further comprising: a gate electrode (62) that is arranged in a region between the first well connection electrode (58) and the second well connection electrode (59) on the insulating film (40) so as to oppose the well region (31); and wherein the cathode region (80, 80A to 80F) is formed at an interval along the second main surface (4) from a gate reference position (PG) immediately below the gate electrode (62).

[C23] The semiconductor device (1) according to any one of C1 to C21, further comprising: a gate wiring (45) that is arranged within the insulating film (40) so as to oppose the well region (31); and wherein the first well connection electrode (58) is embedded in the insulating film (40) at an interval from the gate wiring (45) toward the IGBT region (6), the second well connection electrode (59) is embedded in the insulating film (40) at an interval from the gate wiring (45) toward the peripheral edge of the chip (2), and the cathode region (80, 80A to 80F) is formed at an interval along the second main surface (4) from a gate reference position (PG) immediately below the gate wiring (45).

[C24] The semiconductor device (1) according to C23, further comprising: a gate connection electrode (53) that is embedded in the insulating film (40) so as to be connected to the gate wiring (45); and a gate electrode (62) that is arranged in a region between the first well connection electrode (58) and the second well connection electrode (59) on the insulating film (40) so as to be connected electronically to the gate wiring (45) via the gate connection electrode (53).

[C25] The semiconductor device (1) according to any one of C1 to C24, further comprising: a first conductivity type (p-type) collector region (11) that is formed in the surface layer portion of the second main surface (4); and wherein the cathode region (80) has a second conductivity type impurity concentration that is higher than the first conductivity type impurity concentration of the collector region (11).

[C26] The semiconductor device (1) according to any one of C1 to C25, further comprising: a first conductivity type (p-type) base region (17) that is formed in the surface layer portion of the first main surface (3) within the IGBT region (6).

[C27] The semiconductor device (1) according to C26, wherein the cathode region does not oppose the base region (17).

[C28] The semiconductor device (1) according to C26 or C27, wherein the well region (31) is deeper than the base region (17).

[C29] The semiconductor device (1) according to any one of C26 to C28, wherein the well region (31) is drawn out from the outer peripheral region (8) to the IGBT region (6) and has a portion that is connected to the base region (17).

[C30] The semiconductor device (1) according to any one of C1 to C29, further comprising: a trench gate structure (18) that is formed in the first main surface (3) within the IGBT region (6).

[C31] The semiconductor device (1) according to C30, wherein the cathode region does not oppose the trench gate structure (18).

[C32] The semiconductor device (1) according to C30 or C31, wherein the well region (31) is drawn out from the outer peripheral region (8) to the IGBT region (6) and has a portion that covers the bottom wall of the trench gate structure (18).

[D1] A semiconductor device (1) comprising: a chip (2) that has a first main surface (3) on one side and a second main surface (4) on the other side; an IGBT region (6) that is provided in an inner portion of the first main surface (3); an outer peripheral region (8) that is provided in a peripheral edge portion of the first main surface (3); a first conductivity type (p-type) well region (31) that is formed in a surface layer portion of the first main surface (3) in the outer peripheral region (8) so as to define the IGBT region (6); an insulating film (40) that covers the well region (31); a well connection electrode (57, 58) that is embedded in the insulating film (40) so as to be connected to the well region (31); an emitter pad electrode (66) that is arranged on the insulating film (40) so as to be electrically connected to the well region (31) via the well connection electrode (57, 58); and a second conductivity type (n-type) cathode region (80, 80A to 80F) that is formed in a surface layer portion of the second main surface (4) in the outer peripheral region (8) so as to oppose the well connection electrode (57, 58), and that forms a diode (81) with the well region (31).

[D2] A semiconductor device (1) comprising: a chip (2) that has a first main surface (3) on one side and a second main surface (4) on the other side; an IGBT region (6) that is provided in an inner portion of the first main surface (3); an outer peripheral region (8) that is provided in a peripheral edge portion of the first main surface (3); a first conductivity type (p-type) well region (31) that is formed in a surface layer portion of the first main surface (3) in the outer peripheral region (8) so as to define the IGBT region (6); an insulating film (40) that covers the well region (31); a well connection electrode (57, 59) that is embedded in the insulating film (40) so as to be connected to the well region (31); an emitter electrode (67) that is arranged on the insulating film (40) so as to be electrically connected to the well region (31) via the well connection electrode (57, 59); and a second conductivity type (n-type) cathode region (80, 80A to 80F) that is formed in a surface layer portion of the second main surface (4) in the outer peripheral region (8) so as to oppose the well connection electrode (57, 59), and that forms a diode (81) with the well region (31).

[D3] A semiconductor device (1) comprising: a chip (2) that has a first main surface (3) on one side and a second main surface (4) on the other side; an IGBT region (6) that is provided in an inner portion of the first main surface (3); an outer peripheral region (8) that is provided in a peripheral edge portion of the first main surface (3); a first conductivity type (p-type) well region (31) that is formed in a surface layer portion of the first main surface (3) in the outer peripheral region (8) so as to define the IGBT region (6); an insulating film (40) that covers the well region (31); a first well connection electrode (58) that is embedded in the insulating film (40) so as to be connected to the well region (31); a second well connection electrode (59) that is embedded in the insulating film (40) at an interval from the first well connection electrode (58) toward the peripheral edge of the chip (2) so as to be connected to the well region (31); a gate electrode (62) that is arranged in a region between the first well connection electrode (58) and the second well connection electrode (59) on the insulating film (40) so as to oppose the well region (31); and a second conductivity type (n-type) cathode region (80, 80A to 80F) that is arranged in a surface layer portion of the second main surface (4) at an interval along the second main surface (4) from a gate reference position (PG) immediately below the center of the gate electrode (62) so as to oppose the well region (31), and that forms a diode (81) with the well region (31).

[D4] A semiconductor device (1) comprising: a chip (2) that has a first main surface (3) on one side and a second main surface (4) on the other side; an IGBT region (6) that is provided in an inner portion of the first main surface (3); an outer peripheral region (8) that is provided in a peripheral edge portion of the first main surface (3); a first conductivity type (p-type) well region (31) that is formed in a surface layer portion of the first main surface (3) in the outer peripheral region (8) so as to define the IGBT region (6); an insulating film (40) that covers the well region (31); a gate wiring (45) that is arranged within the insulating film (40) so as to oppose the well region (31); a first well connection electrode (58) that is embedded in the insulating film (40) at an interval from the gate wiring (45) toward the IGBT region (6) so as to be connected to the well region (31); a second well connection electrode (59) that is embedded in the insulating film (40) at an interval from the gate wiring (45) toward the peripheral edge of the chip (2) so as to be connected to the well region (31); and a second conductivity type (n-type) cathode region (80, 80A to 80F) that is arranged in a surface layer portion of the second main surface (4) at an interval along the second main surface (4) from a gate reference position (PG) immediately below a center of the gate wiring (45) so as to oppose the well region (31), and that forms a diode (81) with the well region (31).

Although the embodiments have been described in detail as above, these are merely concrete examples that specify technical contents. Various technical ideas extracted from this description can be appropriately combined together without being limited to the sequential descriptive order in this description, the sequential order of the embodiments, or the like.

What is claimed is:

1. A semiconductor device comprising:
a chip that has a first main surface on one side and a second main surface on the other side;
an IGBT region that is provided in an inner portion of the first main surface;
an outer peripheral region that is provided in a peripheral edge portion of the first main surface;
a first conductivity type well region that is formed in a surface layer portion of the first main surface in the outer peripheral region so as to define the IGBT region;
an insulating film that covers the well region;
a well connection electrode that is embedded in the insulating film so as to be connected to the well region; and
a second conductivity type cathode region that is formed in a surface layer portion of the second main surface in the outer peripheral region so as to oppose the well connection electrode, and that forms a diode with the well region.

2. The semiconductor device according to claim 1, further comprising:
a gate electrode that is arranged on the insulating film at an interval from the well connection electrode so as to oppose the well region.

3. The semiconductor device according to claim 2,
wherein the cathode region is formed at an interval along the second main surface from a position immediately below a center of the gate electrode.

4. The semiconductor device according to claim 2,
wherein the gate electrode is arranged at an interval from the well connection electrode toward the IGBT region.

5. The semiconductor device according to claim 4,
wherein the cathode region is formed at an interval along the second main surface from a position immediately below a center of the gate electrode toward a peripheral edge of the chip.

6. The semiconductor device according to claim 4, further comprising:
an emitter electrode that is arranged on the insulating film at an interval from the gate electrode toward a peripheral edge of the chip, and that is electrically connected to the well region via the well connection electrode; and
wherein the cathode region opposes the emitter electrode.

7. The semiconductor device according to claim 6,
wherein the emitter electrode is arranged only in a region that opposes the well region in a cross-sectional view.

8. The semiconductor device according to claim 2,
wherein the gate electrode is arranged at an interval from the well connection electrode toward a peripheral edge of the chip.

9. The semiconductor device according to claim 8,
wherein the cathode region is formed at an interval along the second main surface from a position immediately below a center of the gate electrode toward the IGBT region.

10. The semiconductor device according to claim 8, further comprising:
an emitter pad electrode that is arranged on the insulating film at an interval from the gate electrode toward the IGBT region, and that is electrically connected to the well region via the well connection electrode; and
wherein the cathode region opposes the emitter pad electrode.

11. The semiconductor device according to claim 2,
wherein the cathode region does not oppose the gate electrode.

12. The semiconductor device according to claim 2, further comprising:
a gate wiring that is arranged within the insulating film so as to oppose the well region; and
a gate connection electrode that is embedded in the insulating film so as to be connected to the gate wiring; and
wherein the gate electrode is electrically connected to the gate wiring via the gate connection electrode.

13. The semiconductor device according to claim 12,
wherein the cathode region is formed at an interval along the second main surface from a position immediately below a center of the gate wiring.

14. The semiconductor device according to claim 12,
wherein the cathode region does not oppose the gate connection electrode.

15. The semiconductor device according to claim 12,
wherein the cathode region does not oppose the gate wiring.

16. The semiconductor device according to claim 12,
wherein the gate electrode is formed narrower than the gate wiring.

17. The semiconductor device according to claim 1,
wherein the cathode region is formed only in a region that opposes the well region in the surface layer portion of the second main surface.

18. The semiconductor device according to claim 1,
wherein the cathode region includes an opposing portion that opposes the well region and a drawer portion that is drawn out from the opposing portion toward a peripheral edge of the chip.

19. The semiconductor device according to claim 18, further comprising:
a first conductivity type field region that is formed in the surface layer portion of the first main surface at an interval from the well region toward the peripheral edge of the chip in the outer peripheral region; and
wherein the drawer portion does not oppose the field region.

20. The semiconductor device according to claim 18, further comprising:
a first conductivity type field region that is formed in the surface layer portion of the first main surface at an interval from the well region toward the peripheral edge of the chip in the outer peripheral region; and
wherein the drawer portion opposes the field region.
